(19) United States
(12) Patent Application Publication
(10) Pub. No.: US 2024/0064964 A1
(43) Pub. Date: Feb. 22, 2024

(54) SEMICONDUCTOR MEMORY DEVICE

(71) Applicant: SAMSUNG ELECTRONICS CO., LTD., SUWON-SI (KR)

(72) Inventors: Jong Min KIM, Suwon-si (KR); Chan-Sic YOON, Suwon-si (KR); Jun Hyeok AHN, Suwon-si (KR)

(21) Appl. No.: 18/191,291

(22) Filed: Mar. 28, 2023

(30) Foreign Application Priority Data
Aug. 19, 2022 (KR) 10-2022-0104243

(51) Int. Cl. H10B 12/00

(52) U.S. Cl. CPC H10B 12/315; H10B 12/485; H10B 12/482; H10B 12/488

(57) ABSTRACT

Provided is a semiconductor memory device. The semiconductor memory device includes a substrate including an active region defined by a device isolation layer, a bit line which is disposed on the substrate and extends in a first direction, a bit line contact which is disposed between the bit line and the substrate and connects the bit line to the active region, a bit line spacer which extends along a sidewall of the bit line, and a bit line contact spacer which extends along a sidewall of the bit line contact and does not extend along the sidewall of the bit line.

### CROSS-REFERENCE TO RELATED APPLICATION

This application claims priority under 35 U.S.C. § 119 to Korean Patent Application No. 10-2022-0104243, filed on Aug. 19, 2022, in the Korean Intellectual Property Office, the contents of which are herein incorporated by reference in their entirety.

### TECHNICAL FIELD

The present disclosure relates to a semiconductor memory device, and more particularly, to a semiconductor memory device including a plurality of wiring lines and buried contacts intersecting each other.

### DISCUSSION OF RELATED ART

As semiconductor devices become more highly integrated, individual circuit patterns are becoming more miniaturized to implement more semiconductor devices in the same area. For example, as the degree of integration of semiconductor devices increases, design rules for components of the semiconductor devices are reduced.

In a highly scaled-down semiconductor device, a process of forming a plurality of wiring lines with a plurality of buried contacts and a plurality of direct contacts interposed between them becomes increasingly complicated and difficult. With limited space between adjacent buried contacts and direct contacts in the highly scaled-down semiconductor device, if the adjacent buried contacts and direct contacts are not properly separated, short circuit may occur. Therefore, it is desirable to develop a robust structure and/or process capable of reliably separating adjacent contacts, so that short circuit between the adjacent contacts in the highly scaled-down semiconductor device may be prevented.

### SUMMARY

Embodiments of the present disclosure provide a semiconductor memory device with enhanced reliability and performance.

According to an embodiment of the present disclosure, there is provided a semiconductor memory device including a substrate including an active region defined by a device isolation layer, a bit line which is disposed on the substrate and extends in a first direction, a bit line contact which is disposed between the bit line and the substrate and connects the bit line to the active region, a bit line spacer which extends along a sidewall of the bit line, and a bit line contact spacer which extends along a sidewall of the bit line contact and does not extend along the sidewall of the bit line.

According to an embodiment of the present disclosure, there is provided a semiconductor memory device including a substrate which includes first to third active regions defined by a device isolation layer, the second active region being disposed between the first active region and the third active region, a bit line contact which is disposed on the substrate and connected to the second active region, a first storage contact which is disposed on the substrate and connected to the first active region, a second storage contact which is disposed on the substrate and connected to the third active region, a bit line contact spacer which is disposed on the substrate and is disposed between the bit line contact and the first storage contact and between the bit line contact and the second storage contact, and a bit line which is disposed on the bit line contact, extends in a first direction, and is in contact with an upper surface of the bit line contact spacer.

According to an embodiment of the present disclosure, there is provided a semiconductor memory device including a substrate which includes an active region defined by a device isolation layer and extending in a first direction, the active region including a first region and second regions defined at opposite sides of the first region, a word line which extends in a second direction in the substrate and the device isolation layer and crosses the first region of the active region and the second region of the active region, a bit line which is disposed on the substrate and the device isolation layer, extends in a third direction orthogonal to the second direction, and is connected to the first region of the active region, a bit line contact which is disposed between the bit line and the substrate and connected to the bit line, a width of an upper surface of the bit line contact in the second direction being smaller than a width of a bottom surface of the bit line in the second direction, a storage contact which is disposed on the substrate and connected to a second region of an other active region adjacent to the active region, a storage pad which is disposed on the storage contact and connected to the storage contact, and a capacitor which is disposed on the storage pad and connected to the storage pad.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the accompanying drawings, in which:

FIG. 1 is a schematic layout view of a semiconductor memory device according to an embodiment of the present disclosure;

FIG. 2 is a layout view of only word lines and active regions of FIG. 1;

FIG. 3 is a cross-sectional view taken along line A-A of FIG. 1;

FIG. 4 is a cross-sectional view taken along line B-B of FIG. 1;

FIG. 5 is an enlarged view of portion P of FIG. 3;

FIGS. 6 and 7 are views for describing a semiconductor memory device according to an embodiment of the present disclosure;

FIGS. 8 and 9 are views for describing a semiconductor memory device according to an embodiment of the present disclosure;

FIGS. 10 to 14 are views each for describing a semiconductor memory device according to an embodiment of the present disclosure;

FIG. 15 is a view for describing a semiconductor memory device according to an embodiment of the present disclosure;

FIGS. 16 to 40 are views illustrating intermediate stages of fabrication, provided to explain a method of fabricating a semiconductor memory device according to an embodiment of the present disclosure; and

FIGS. 41 to 44 are views each for describing a method of fabricating a semiconductor memory device according to an embodiment of the present disclosure.

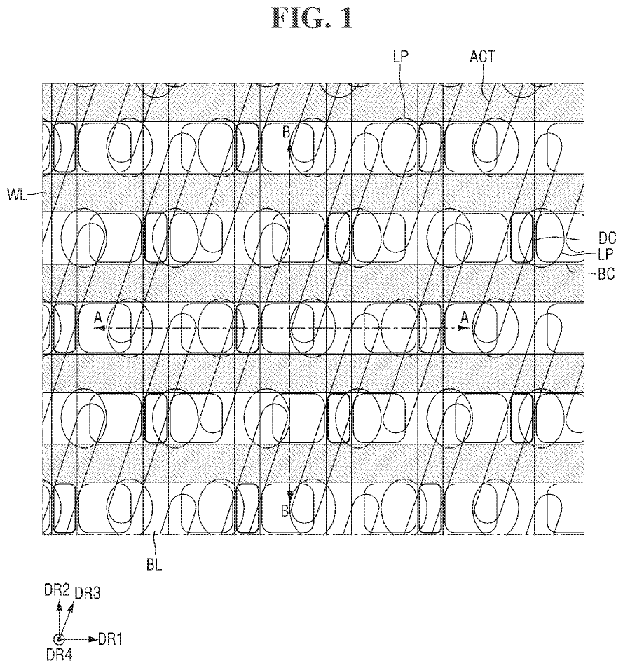

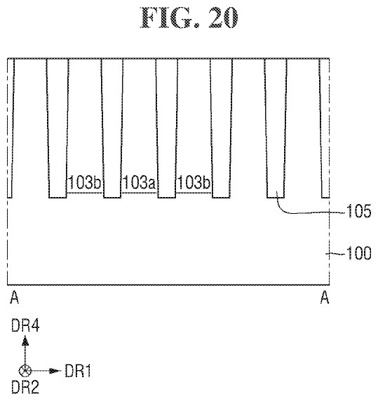

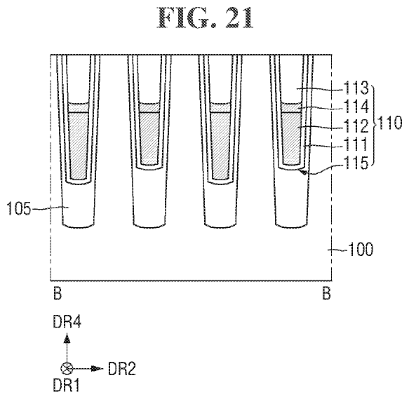

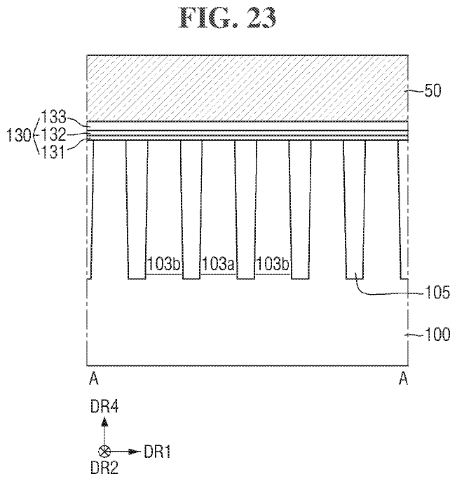

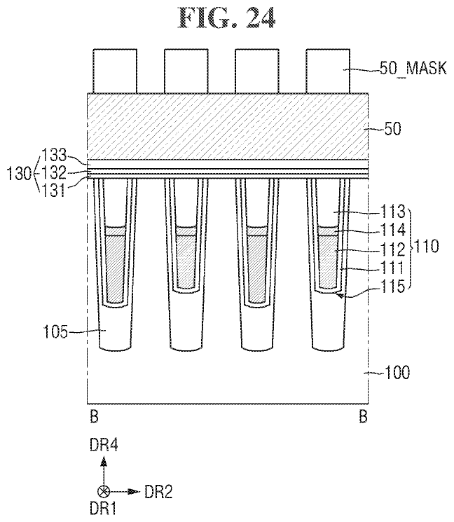

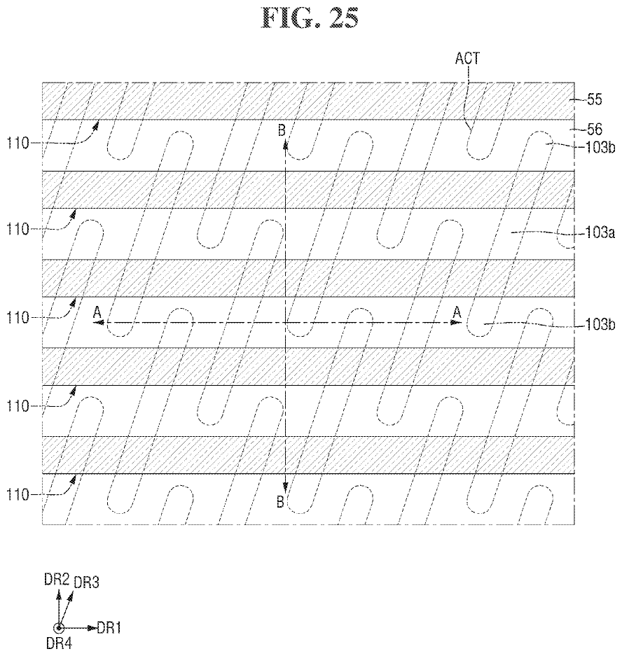

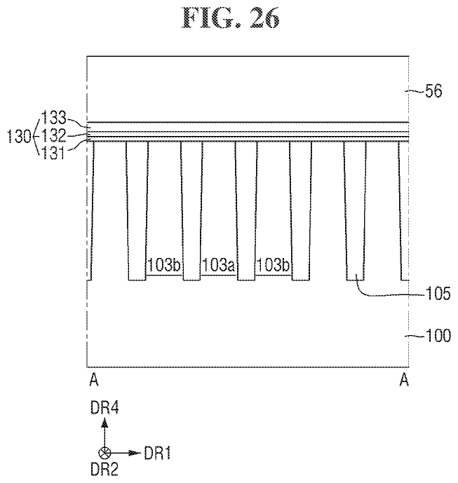

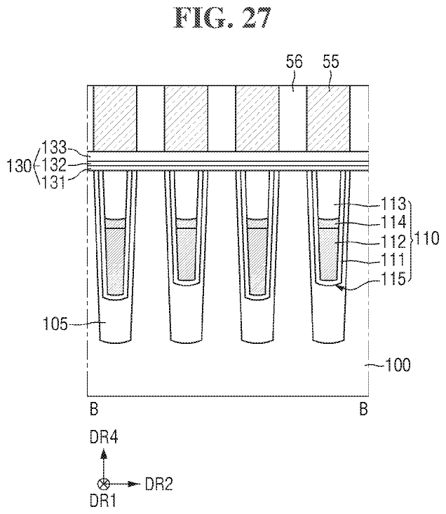

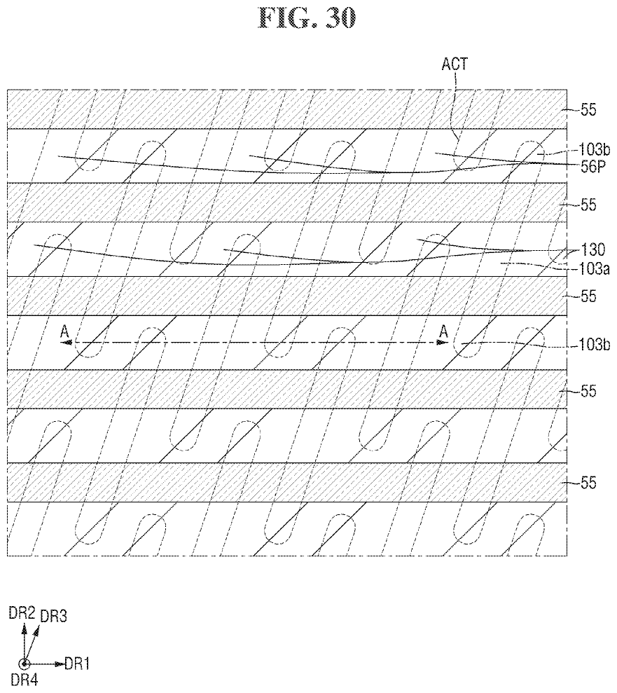

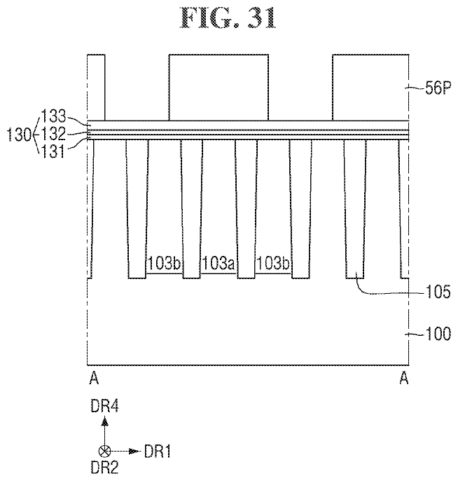

Since the drawings in FIGS. 1-44 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

It will be understood that, although the terms “first”, “second”, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure. Similarly, the second element, the second component or the second section could also be termed the first element, the first component or the first section.

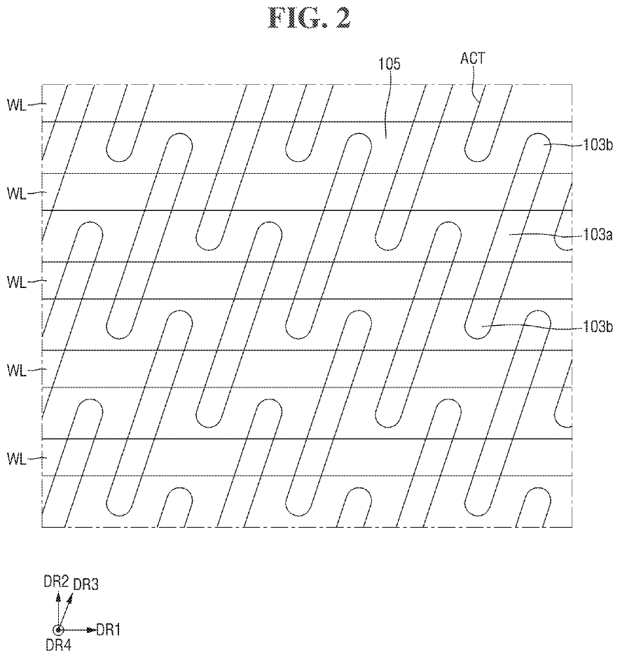

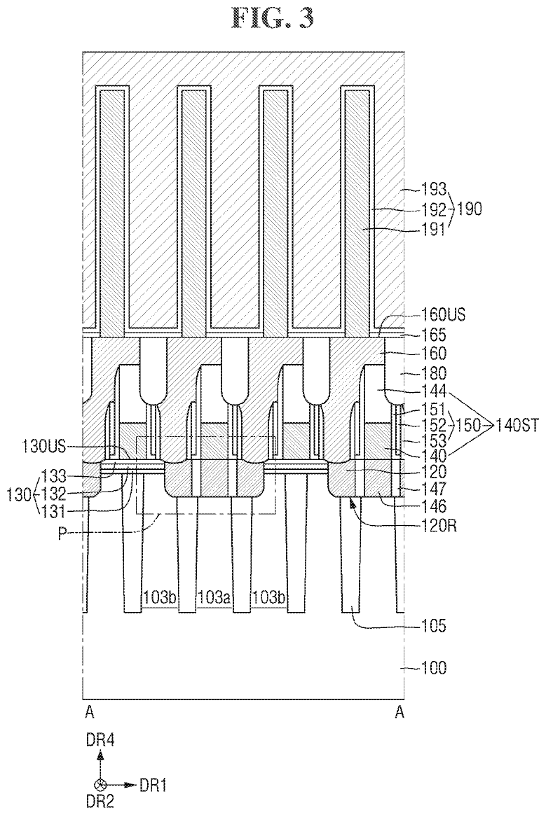

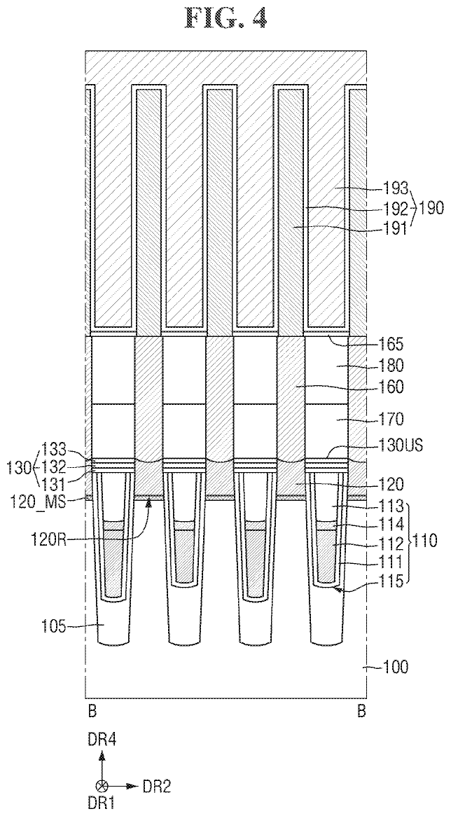

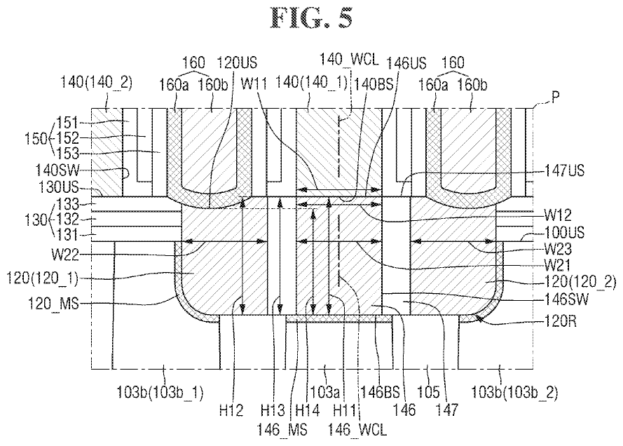

FIG. 1 is a schematic layout view of a semiconductor memory device according to an embodiment of the present disclosure. FIG. 2 is a layout view of only word lines and active regions of FIG. 1. FIG. 3 is a cross-sectional view taken along line A-A of FIG. 1. FIG. 4 is a cross-sectional view taken along line B-B of FIG. 1. FIG. 5 is an enlarged view of portion P of FIG. 3.

In the drawings of the semiconductor device according to embodiments of the present disclosure, a dynamic random access memory (DRAM) is illustrated by way of examples.

Referring to FIGS. 1 and 2, the semiconductor memory device according to an embodiment of the present disclosure may include a plurality of cell active regions ACT.

The cell active regions ACT may be defined by a cell device isolation layer 105 formed in a substrate 100 (see FIG. 3). When viewed in plan, the cell active regions ACT may correspond to portions of the substrate 100 that are surrounded by the cell device isolation layer 105 (see FIG. 2). As design rules of the semiconductor device are reduced, the cell active regions ACT may be disposed in the form of diagonal or oblique bars as illustrated in the drawings. For example, the cell active regions ACT may extend in a third direction DR3 The cell active regions ACT may be arranged in parallel to each other such that one of the cell active regions ACT may have an end portion adjacent to a central portion of a neighboring one of the cell active regions ACT.

A plurality of gate electrodes may extend in a first direction DR1 across the cell active regions ACT. The gate electrodes may extend parallel to each other. The gate electrodes may be, for example, a plurality of word lines WL. The word lines WL may be disposed at equal intervals in the first direction DR1. A width of each word line WL or an interval between the word lines WL adjacent to each other may be determined according to the design rules. For example, the word lines WL may run across the cell active regions ACT, and may be disposed within grooves (cell gate trench 115 of FIG. 4) formed in the cell device isolation layer 105 (see FIG. 4) and the cell active regions ACT.

Each of the cell active regions ACT may be divided into three parts by two word lines WL extending in the first direction DR1. Each of the cell active regions ACT may include storage connection regions 103b and a bit line connection region 103a. The bit line connection region 103a may be located in a middle part of each of the cell active regions ACT, and the storage connection regions 103b may be located at opposite ends of each of the cell active regions ACT, respectively.

The bit line connection region 103a may be a region connected to a bit line BL, and the storage connection region 103b may be a region connected to an information storage part 190 (see FIG. 3). In other words, the bit line connection region 103a may be a common drain region, and the storage connection region 103b may be a source region. Each of the word lines WL, the bit line connection region 103a adjacent to the word line WL, and the storage connection region 103b adjacent to the word line WL may form a transistor.

A plurality of bit lines BL may be disposed on the word lines WL to extend in a second direction DR2 orthogonal to the word lines WL. For example, the second direction DR2 may be orthogonal to the first direction DR1. The bit lines BL may extend parallel to each other. The bit lines BL may be disposed at equal intervals in the first direction DR1. A width of each bit line BL or an interval between the bit lines BL adjacent to each other may be determined according to the design rules.

A fourth direction DR4 may be orthogonal to the first direction DR1, the second direction DR2, and the third direction DR3. The fourth direction DR4 may be a thickness direction of the substrate 100.

The semiconductor memory device according to an embodiment of the present disclosure may include various contact arrays formed on the cell active regions ACT. The various contact arrays may include, for example, direct contacts DC, buried contacts BC, and landing pads LP.

Here, the direct contacts DC may be contacts that electrically connect the cell active regions ACT to the bit lines BL. The buried contacts BC may be contacts that connect the cell active regions ACT to lower electrodes 191 (see FIG. 3) of capacitors. The buried contacts BC may each be disposed between a pair of neighboring bit lines BL in a plan view, and may be spaced apart from each other in the first direction DR1. In addition, the buried contacts BC may each be disposed between a pair of neighboring word lines WL in a plan view, and may be spaced apart from each other in the second direction DR2. In an embodiment of the present disclosure, in a plan view, two adjacent buried contacts BC may be symmetrically disposed against a bit line BL interposed therebetween, while two adjacent buried contacts BC may not be symmetrically disposed against a word line WL interposed therebetween. Due to the arrangement structure, contact areas between the buried contacts BC and the cell active regions ACT may be small. Therefore, the conductive landing pads LP may be introduced to increase the contact areas of the buried contacts BC with the cell active regions ACT and also to increase the contact areas of the buried contacts BC with the lower electrodes 191 (see FIG. 3) of the capacitors.

The landing pads LP may be disposed between the buried contacts BC and the lower electrodes 191 (see FIG. 3) of the capacitors, and may be electrically connected to the buried contacts BC and the lower electrodes 191 of the capacitors. The increased contact areas by the introduction of the landing pads LP may reduce contact resistance between the cell active regions ACT and the lower electrodes 191 of the capacitors.

The direct contacts DC may be connected to the bit line connection regions 103a. The buried contacts BC may be connected to the storage connection regions 103b. Since the buried contacts BC are disposed at opposite ends of each cell active region ACT, the landing pads LP may be disposed adjacent to opposite ends of each cell active region ACT so as to partially overlap the buried contacts BC. For example, the buried contacts BC (storage contacts 120 of FIGS. 3 and 4) may be formed to overlap the cell active regions ACT and the cell device isolation layer 105 (see FIGS. 3 and 4) disposed between adjacent word lines WL (cell gate electrodes 112 of FIG. 4) and between adjacent bit lines BL (cell conductive lines 140 of FIG. 3).

The word lines WL may be buried in the substrate 100. The word lines WL may cross the cell active regions ACT located between the direct contacts DC or the buried contacts BC. As illustrated, two word lines WL may cross one cell active region ACT. Since the cell active regions ACT extend in the third direction DR3, the word lines WL may be at an angle of less than 90 degrees to the cell active regions ACT. For example, the bit lines BL extending in the second direction DR2 may be orthogonal to the word lines WL extending in the first direction DR1, while the active region ACT may have a bar shape extending in the third direction DR3, and thus, as shown in FIG. 1, the third direction DR3 may be inclined by a predetermined angle with respect to the first direction DR1 or the second direction DR2. The predetermined angle may vary to some degree. In an embodiment of the present disclosure, the predetermined angle may range from about 10° to about 80°.

Two adjacent buried contacts BC may be symmetrically disposed against one direct contact DC placed on one of the cell active regions ACT. For example, the direct contacts DC and the buried contacts BC may be spaced apart from each other in the first direction DR1. The landing pads LP may be disposed on the cell active regions ACT in a zigzag manner in the second direction DR2 in which the bit lines BL extend. In addition, the landing pads LP may overlap the same side of each bit line BL in the first direction D1 in which the word lines WL extend.

For example, each landing pad LP of a first line may overlap a left side of a corresponding bit line BL, and each landing pad LP of a second line may overlap a right side of the corresponding bit line BL.

Referring to FIGS. 1 to 5, the semiconductor memory device according to an embodiment of the present disclosure may include a plurality of cell gate structures 110, a plurality of bit line structures 140ST, a plurality of storage contacts 120, a plurality of bit line contacts 146, and an information storage part 190.

The substrate 100 may be a silicon (Si) substrate or silicon-on-insulator (SOI). Alternatively, the substrate 100 may include, but is not limited to, silicon germanium (SiGe), silicon germanium on insulator (SGOI), indium antimonide (InSb), lead telluride (PbTe), indium arsenide (InAs), indium phosphide (InP), gallium arsenide (GaAs), gallium phosphide (GaP), or gallium antimonide (GaSb). In addition, the substrate 100 may include one or more semiconductor layers or structures and may include active or operable portions of semiconductor devices.

The cell device isolation layer 105 may be formed in the substrate 100. The cell device isolation layer 105 may have a shallow trench isolation (STI) structure having superior element isolation characteristics. The cell device isolation layer 105 may define the cell active regions ACT in a memory cell region.

The cell active regions ACT defined by the cell device isolation layer 105 may be shaped like long islands, each including a short axis and a long axis as illustrated in FIGS. 1 and 2. The cell active regions ACT may be shaped like diagonal lines at an angle of less than 90 degrees to the word lines WL formed in the cell device isolation layer 105. In addition, the cell active regions ACT may be shaped like diagonal lines at an angle of less than 90 degrees to the bit lines BL formed on the cell device isolation layer 105. By disposing the plurality of cell active regions ACT in a direction of a diagonal line or an oblique line, a maximum possible distance between contacts may be provided for the semiconductor memory device.

The cell device isolation layer 105 may include, but is not limited to, for example, at least one of a silicon oxide (SiO₂) layer, a silicon nitride (Si₃N₄) layer, or a silicon oxynitride (SiON) layer.

Although the cell device isolation layer 105 is formed as a single insulating layer in the drawings, this is merely for ease of description, and the present disclosure is not limited thereto. The cell device isolation layer 105 may be formed of a single insulating layer or a plurality of insulating layers depending on the distance from the adjacent cell active region ACT.

In FIGS. 3 and 5, an upper surface of the cell device isolation layer 105 and an upper surface 100US of the substrate are coplanar with each other. However, this is merely for ease of description, and the present disclosure is not limited thereto.

The cell gate structures 110 may be formed in the substrate 100 and the cell device isolation layer 105. The cell gate structures 110 may be formed across the cell device isolation layer 105 and the cell active regions ACT defined by the cell device isolation layer 105.

Each of the cell gate structures 110 may include a cell gate trench 115, a cell gate insulating layer 111, a cell gate electrode 112, a cell gate capping pattern 113, and a cell gate capping conductive layer 114.

Here, the cell gate electrode 112 may correspond to a word line WL. For example, the cell gate electrode 112 may be the word line WL of FIG. 1. Unlike in the drawings, in an embodiment of the present disclosure, the cell gate structure 110 may not include the cell gate capping conductive layer 114.

The cell gate trench 115 may be relatively deep in the cell device isolation layer 105 and relatively shallow in the cell active regions ACT. A bottom surface of the word line WL may be curved. That is, the depth of the cell gate trench 115 in the cell device isolation layer 105 may be greater than the depth of the cell gate trench 115 in the cell active region ACT.

The cell gate insulating layer 111 may extend along sidewalls and a bottom surface of the cell gate trench 115. The cell gate insulating layer 111 may extend along the profile of at least a part of the cell gate trench 115.

The cell gate insulating layer 111 may include at least one of, for example, silicon oxide (SiO₂), silicon nitride (Si₃N₄), silicon oxynitride (SiON), or a high dielectric constant (high-k) material having a dielectric constant higher than that of silicon oxide (SiO₂). The high-k material may include at least one of, for example, hafnium oxide (HfO₂), hafnium silicon oxide (HfSiO₄), hafnium zirconium oxide (HfZrO₄), hafnium tantalum oxide (Hf₂Ta₂O₉), hafnium aluminum oxide (HfA₁O₃), lanthanum oxide (La₂O₃), lanthanum aluminum oxide (LaAlO₃), zirconium oxide (ZrO₂), zirconium silicon oxide (ZrSiO₄), tantalum oxide (Ta₂O₅), titanium oxide (TiO₂), barium strontium titanium oxide (BaSrTi₂O₆), barium titanium oxide (BaTiO₃), strontium titanium oxide (SrTiO₃), yttrium oxide (Y₂O₃), lithium oxide (Li₂O), aluminum oxide (Al₂O₃), lead scandium tantalum oxide (Pb(Sc,Ta)O₃), lead zinc niobate [Pb(Zn_{1/3}Nb_{2/3})O₃], or combinations thereof.

The cell gate electrode 112 may be formed on the cell gate insulating layer 111. The cell gate electrode 112 may fill a part of the cell gate trench 115. The cell gate capping conductive layer 114 may extend along an upper surface of the cell gate electrode 112.

The cell gate electrode 112 may include at least one of, for example, a metal, a metal alloy, a conductive metal nitride, a conductive metal carbonitride, a conductive metal carbide, a metal silicide, a doped semiconductor material, a conductive metal oxynitride, or a conductive metal oxide. The cell gate electrode 112 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), ruthenium titanium nitride (RuTiN), titanium silicide (TiSi₂), tantalum silicide (TaSi₂), nickel silicide (NiSi₂), cobalt silicide (CoSi₂), iridium oxide (IrOₓ), ruthenium oxide (RuOₓ), or combinations thereof.

The cell gate capping conductive layer 114 may include, but is not limited to, at least one of, for example, polysilicon (p-Si), polysilicon-germanium (p-SiGe), amorphous silicon (a-Si), or amorphous silicon-germanium (a-SiGe).

The cell gate capping pattern 113 may be disposed on the cell gate electrode 112 and the cell gate capping conductive layer 114. The cell gate capping pattern 113 may fill the other part of the cell gate trench 115 excluding the part in which the cell gate electrode 112 and the cell gate capping conductive layer 114 are formed. Although the cell gate insulating layer 111 is illustrated as extending along sidewalls of the cell gate capping pattern 113, the present disclosure is not limited thereto. For example, in an embodiment of the present disclosure, the cell gate insulating layer 111 may extend along the side walls of the cell gate electrode 112 and the cell gate capping conductive layer 114, but may not extend along the side walls of the cell gate capping pattern 113. For example, the top surface of the cell gate insulating layer 111 may be covered by the cell gate capping pattern 113.

The cell gate capping pattern 113 may include at least one of, for example, silicon nitride (Si₃N₄), silicon oxynitride (SiON), silicon oxide (SiO₂), silicon carbonitride (SiCN), silicon oxycarbonitride (SiOCN), or combinations thereof.

Although an upper surface of the cell gate capping pattern 113 is coplanar with the upper surface of the cell device isolation layer 105 in FIG. 4, the present disclosure is not limited thereto.

An impurity doping region may be formed on at least one side of each cell gate structure 110. The impurity doping region may be a source/drain region of a transistor. The impurity doping region may be formed on each storage connection region 103b and each bit line connection region 103a of FIG. 2.

In FIG. 2, when the transistor including each word line WL, the bit line connection region 103a adjacent to the word line WL, and the storage connection region 103b adjacent to the word line WL is an NMOS transistor, the storage connection region 103b and the bit line connection region 103a may each be doped with n-type impurities. The n-type impurities may include at least one of, for example, phosphorus (P), arsenic (As), antimony (Sb), or bismuth (Bi). When the transistor including each word line WL, the bit line connection region 103a adjacent to the word line WL, and the storage connection region 103b adjacent to the word line WL is a PMOS transistor, the storage connection region 103b and the bit line connection region 103a may each be doped with p-type impurities, for example, boron (B), aluminum (Al), or gallium (Ga).

The bit line contacts 146 and the storage contacts 120 may be disposed in contact recesses 120R. The contact recesses 120R may be formed in the substrate 100 and the cell device isolation layer 105.

In a cross-sectional view, each contact recess 120R may be formed over one bit line connection region 103a and two storage connection regions 103b. For example, in FIG. 5, the bit line connection region 103a may be disposed between a first storage connection region 103b_1 and a second storage connection region 103b_2. The bit line connection region 103a, the first storage connection region 103b_1, and the second storage connection region 103b_2 may be respectively included in different cell active regions ACT in FIG. 1. That is, the bit line connection region 103a, the first storage connection region 103b_1, and the second storage connection region 103b_2 that are exposed by one contact recess 120R may be respectively included in first to third cell active regions ACT divided by the cell device isolation layer 105. For example, the contact recess 120R may be widely opened over the first storage connection region 103b_1 of the first cell active region ACT, the bit line connection region 103a of the second cell active region ACT and the second storage connection region 103b_2 of the third cell active region. In other words, one contact recess 120R may be widely opened over three adjacent cell active regions ACT, so as to accommodate one bit line contact 146 and two storage contacts 120.

The bit line contacts 146 are disposed on the substrate 100. The bit line contacts 146 may be formed between cell conductive lines 140 and the substrate 100.

The bit line contact 146 may be formed between the bit line connection region 103a of the cell active region ACT and each cell conductive line 140. The bit line contacts 146 connect the cell conductive lines 140 to the substrate 100. The bit line contacts 146 may be connected to the bit line connection regions 103a. For example, the bit line contacts 146 may connect the cell conductive lines 140 to the bit line connection regions 103a of the cell active regions ACT.

The bit line contacts 146 may include an upper surface 146US of the bit line contact connected to the cell conductive line 140. Although a width of the bit line contact 146 in the first direction DR1 may be equal to a width of the cell conductive line 140 in the first direction DR1, the present disclosure is not limited thereto. In a cross-sectional view, an upper surface 146US of the bit line contact is illustrated as a flat surface, but the present disclosure is not limited thereto.

The bit line contact 146 includes a bottom surface 146BS connected to the substrate 100. In a cross-sectional view, the bottom surface 146BS of the bit line contact is illustrated as a flat surface, but the present disclosure is not limited thereto. The bit line contacts 146 may correspond to the direct contacts DC of FIG. 1.

The storage contacts 120 may be disposed on the substrate 100. The storage contacts 120 may be disposed on opposite sides of the bit line contact 146 in the contact recess 120R.

The storage contact 120 may be connected to the storage connection region 103b. Here, the storage contacts 120 may correspond to the buried contacts BC of FIG. 1.

The storage contact 120 may include a first storage contact 120_1 and a second storage contact 120_2 that are disposed in the contact recess 120R. The bit line contact 146 may be disposed between the first storage contact 120_1 and the second storage contact 120_2. The first storage contact 120_1 may be connected to the first storage connection region 103b_1. The second storage contact 120_2 may be connected to the second storage connection region 103b_2. For example, the first storage contact 120_1, the second storage contact 120_2 and the bit line contact 146 may all be disposed within the contact recess 120R.

In a cross-sectional view as shown in FIGS. 3 and 5, the upper surface 120US of the storage contact may include a flat portion and a concave portion. A bit line spacer 150, which will be described below, may cover the flat portion of the upper surface 120US of the storage contact. A storage pad 160, which will be described below, may cover the concave portion of the upper surface 120US of the storage contact.

Unlike in the drawings, the bit line spacer 150 may not cover at least a part of the upper surface 120US of the storage contact. In this case, in a cross-sectional view, the entire upper surface 120US of the storage contact may be concave. Alternatively, the upper surface 120US of the storage contact may include only one flat portion, and in this case, the storage pad 160 may cover a portion or an entirety of the one flat portion of the upper surface 120US of the storage contact.

The bit line contacts 146 may include a material the same as that of the storage contacts 120. The bit line contacts 146 and the storage contacts 120 are formed at the same level. Here, the expression “the same level” means that the bit line contacts 146 and the storage contacts 120 are formed by the same fabrication process.

The bit line contacts 146 and the storage contacts 120 may include a conductive material including, for example, metal. The conductive material may include, but is not limited to, for example, a metal, a metal alloy, a metal nitride, a metal carbonitride, or the like.

In FIGS. 3 and 5, a storage contact silicide layer 120_MS may be disposed between the storage contact 120 and the substrate 100. A bit line contact silicide layer 146_MS may be disposed between the bit line contact 146 and the substrate 100.

The storage contact silicide layer 120_MS and the bit line contact silicide layer 146_MS include the same material. The storage contact silicide layer 120_MS and the bit line contact silicide layer 146_MS include a metal silicide material. For example, when the bit line contacts 146 and the storage contact 120 include a conductive material which is metal, the metal silicide material of the storage contact silicide layer 120_MS and the bit line contact silicide layer 146_MS may provide reliable metal-semiconductor contact between the substrate 100 and the storage contact 120 and the bit line contact 146.

Bit line contact spacers 147 are disposed in the contact recess 120R. The bit line contact spacer 147 is disposed between the bit line contact 146 and the storage contact 120. For example, the bit line contact spacer 147 is disposed between the bit line contact 146 and the first storage contact 120_1 and between the bit line contact 146 and the second storage contact 120_2. With two bit line contact spacers 147 formed within the contact recess 120R, the bit line contact 146 and the storage contacts 120 may be reliably separated. Also, with this structure configuration, even if the scaling progresses further, reliable electrical separation between the bit line contact 146 and the storage contacts 120 may be possible.

The bit line contact spacer 147 may extend along sidewalls 146SW of the bit line contact. The bit line contact spacer 147 extends along the second direction DR2. The bit line contact spacer 147 may be in contact with the bit line contact 146 and the storage contact 120.

The bit line contact spacer 147 electrically isolates the bit line contact 146 from the storage contact 120. The bit line contact spacer 147 includes an insulating material. The bit line contact spacer 147 may include at least one of, for example, silicon oxycarbide (SiOC), silicon nitride (Si₃N₄), silicon oxynitride (SiON), silicon oxide (SiO₂), silicon carbonitride (SiCN), or silicon oxycarbonitride (SiOCN). The bit line contact spacer 147 may be formed as a single layer.

In a cross-sectional view as shown in FIGS. 3 and 5, the upper surface 146US of the bit line contact may be even with or higher than the upper surface 120US of the storage contact based on the bottom surface 146BS of the bit line contact. A height H11 from the bottom surface 146B S of the bit line contact to the upper surface 146US of the bit line contact may be equal to or greater than a height from the bottom surface 146BS of the bit line contact to the upper surface 120US of the storage contact. For example, the height H11 of the bit line contact 146 may be equal to or greater than a height H12 of the storage contact 120.

When the entire upper surface 120US of the storage contact is recessed while storage pads 160 are formed, the entire surface 120US of the storage contact may be concave, unlike in the drawings. In this case, the upper surface 146US of the bit line contact may be higher than the upper surface 120US of the storage contact with respect to the bottom surface 146B S of the bit line contact.

The height H11 from the bottom surface 146BS of the bit line contact to the upper surface 146US of the bit line contact may be equal to a height from the bottom surface 146BS of the bit line contact to an upper surface 147US of the bit line contact spacer. The height from the bottom surface 146BS of the bit line contact to the upper surface 120US of the storage contact may be equal to or smaller than the height from the bottom surface 146B S of the bit line contact to the upper surface 147US of the bit line contact spacer.

A height H13 of the bit line contact spacer 147 may be equal to the height H11 of the bit line contact 146. The height H13 of the bit line contact spacer 147 may be equal to the height H12 of the storage contact 120. Alternatively, the height H13 of the bit line contact spacer 147 may be greater than the height H12 of the storage contact 120.

At the upper surface 100US of the substrate, a width W22 of the first storage contact 120_1 in the first direction DR1 may be equal to a width W23 of the second storage contact 120_2 in the first direction DR1. In an embodiment of the present disclosure, at the upper surface 100US of the substrate, the width W22 of the first storage contact 120_1 in the first direction DR1 may be equal to a width W21 of the bit line contact 146 in the first direction DR1. In an embodiment of the present disclosure, at the upper surface 100US of the substrate, the width W22 of the first storage contact 120_1 in the first direction DR1 may be greater than the width W21 of the bit line contact 146 in the first direction DR1.

The width W22 of the storage contact 120_1 and the width W21 of the bit line contact 146 are compared on the upper surface 100US of the substrate, but the present disclosure is not limited thereto. The width W22 of the first storage contact 120_1 and the width W21 of the bit line contact 146 may be compared on an upper surface 130US of a cell insulating layer which will be described below.

In a cross-sectional view, at least one of opposite sidewalls in the first direction DR1 of the first storage contact 120_1 may not extend to the upper surface 130US of the cell insulating layer. In this case, the width W22 of the first storage contact 120_1 may be measured by virtually extending the sidewalls of the first storage contact 120_1 to the upper surface 130US of the cell insulating layer.

Each bit line structure 140ST may include the cell conductive line 140, the cell line capping layer 144, and the bit line spacer 150.

The cell conductive lines 140 may be disposed on the substrate 100 and the cell device isolation layer 105 in which the cell gate structures 110 are formed. The cell conductive lines 140 may extend in the second direction DR2. The cell conductive line 140 is disposed on the bit line contact 146. The bottom surface 140BS of the cell conductive line is in contact with the upper surface 146US of the bit line contact.

The cell conductive line 140 may intersect the cell device isolation layer 105 and a cell active region ACT defined by the cell device isolation layer 105. For example, the cell conductive line 140 may intersect the cell active region ACT at the bit line connection region 103a. The bit line contact 146 may be formed between the bit line connection region 103a of the cell active region ACT and the cell conductive line 140. The cell conductive line 140 may be formed to intersect the cell gate structures 110. Here, the cell conductive lines 140 may correspond to the bit lines BL. For example, the cell conductive lines 140 may be the bit lines BL of FIG. 1.

The cell conductive lines 140 may include at least one of, for example, a semiconductor material doped with impurities, a conductive silicide compound, a conductive metal nitride, a two-dimensional (2D) material, a metal, or a metal alloy. In the semiconductor memory device according to an embodiment of the present disclosure, the 2D material may be a metallic material and/or a semiconductor material. The 2D material may include 2D allotrope or 2D compound, and may include, but is not limited to, at least one of, for example, graphene, molybdenum disulfide (MoS₂), molybdenum diselenide (MoSe₂), tungsten diselenide (WSe 2), or tungsten disulfide (WS 2). That is, since the above-mentioned 2D materials are only listed by way of example, the 2D materials that may be included in the semiconductor memory device of the present disclosure are not limited by the above-mentioned materials.

The cell conductive line 140 is illustrated as a single layer. However, this is merely for ease of description, and the present disclosure is not limited thereto. For example, unlike in the drawings, the cell conductive line 140 may include a plurality of conductive layers where conductive materials are stacked.

In the semiconductor memory device according to an embodiment of the present disclosure, the width W11 of the bottom surface 140BS of the cell conductive line in the first direction DR1 may be equal to the width W12 of the upper surface 146US of the bit line contact in the first direction DR1.

The cell conductive line 140 may include a width center line 140_WCL. The bit line contact 146 may include a width center line 146_WCL. For example, in the cell conductive line 140, the width center line 140_WCL of the cell conductive line may be a virtual line extending in the fourth direction DR4 from the center of the bottom surface 140B S of the cell conductive line. The center of the bottom surface 140BS of the cell conductive line may be a point bisecting the width W11 of the bottom surface 140BS of the cell conductive line in the first direction DR1.

In the semiconductor memory device according to an embodiment of the present disclosure, the width center line 140_WCL of the cell conductive line may be aligned with the width center line 146_WCL of the bit line contact in the fourth direction DR4. In other words, the width center line 146_WCL of the bit line contact may pass the center of the bottom surface 140BS of the cell conductive line.

In a cross-sectional view as shown in FIGS. 3 and 5, the entire bottom surface 140BS of the cell conductive line may be in contact with the entire upper surface 146US of the bit line contact. The bottom surface 140BS of the cell conductive line may not be in contact with the upper surface 147US of the bit line contact spacer.

The cell line capping layer 144 may be disposed on the cell conductive line 140. The cell line capping layer 144 may extend along the upper surface of the cell conductive line 140 in the second direction DR2. The cell line capping layer 144 may include at least one of, for example, silicon nitride (Si₃N₄), silicon oxynitride (SiON), silicon carbonitride (SiCN), or silicon oxycarbonitride (SiOCN).

In the semiconductor memory device according to an embodiment of the present disclosure, the cell line capping layer 144 may include a silicon nitride (Si₃N₄) layer. The cell line capping layer 144 is illustrated as a single layer, but the present disclosure is not limited thereto.

The bit line spacer 150 may be disposed on the sidewall 140SW of the cell conductive line and a sidewall of the cell line capping layer 144. The bit line spacer 150 may extend in the second direction DR2.

The bit line spacer 150 extend along the sidewall 140SW of the cell conductive line and the sidewall of the cell line capping layer 144. The bit line spacer 150 may be in contact with the sidewall 140SW of the cell conductive line and the sidewall of the cell line capping layer 144.

The bit line spacer 150 is disposed on the upper surface 147US of the bit line contact spacer. At least one of a pair of bit line spacers 150 disposed on the sidewalls 140SW of the cell conductive line may be in contact with the upper surface 147US of the bit line contact spacer. For example, some of the bit line spacers 150 may be in contact with the cell insulating layer 130, and may not be in contact with the bit line contact spacer 147.

The bit line spacer 150 does not extend along the sidewall 146SW of the bit line contact. The bit line spacer 150 is not in contact with the sidewall 146SW of the bit line contact. For example, the bit line contact spacer 147 does not extend along the sidewall 140SW of the cell conductive line.

The bit line spacer 150 may have a multilayer structure. The bit line spacer 150 includes a multilayer. For example, the bit line spacer 150 may have a trilayer structure, and may include a first spacer 151, a second spacer 152, and a third spacer 153, but the present disclosure is not limited thereto. For example, the bit line spacer 150 may be a dual layer, or include four or more layers.

The first spacer 151 is in contact with the sidewalls 140SW of the cell conductive line but not in contact with the sidewalls 146SW of the bit line contact. Each of the layers included in the bit line spacer 150 may include, but is not limited to, at least one of, for example, a silicon oxide (SiO₂) layer, a silicon nitride (Si₃N₄) layer, a silicon oxynitride (SiON) layer, a silicon oxycarbonitride (SiOCN) layer, or air.

The cell insulating layer 130 may be formed on the substrate 100 and the cell device isolation layer 105. For example, the cell insulating layer 130 may be formed on the substrate 100, in which the bit line contacts 146 and the storage contacts 120 are not formed, and on the upper surface of the cell device isolation layer 105. The cell insulating layer 130 may be formed between the substrate 100 and the cell conductive lines 140 and between the cell device isolation layer 105 and the cell conductive lines 140. The bit line spacers 150 are disposed on the upper surface 130US of the cell insulating layer.

The cell insulating layer 130 may be a single layer. However, as illustrated, the cell insulating layer 130 may be a multilayer including a first cell insulating layer 131, a second cell insulating layer 123, and a third cell insulating layer 133. For example, the first cell insulating layer 131 may include a silicon oxide (SiO₂) layer, the second cell insulating layer 132 may include a silicon nitride (Si₃N₄) layer, and the third cell insulating layer 133 may include a silicon oxide (SiO₂) layer. However, the present disclosure is not limited thereto. Unlike in the drawings, the cell insulating layer 130 may be a dual layer including a silicon oxide (SiO₂) layer and a silicon nitride (Si₃N₄) layer, but the present disclosure is not limited thereto.

In a cross-sectional view as shown in FIGS. 3 and 5, the upper surface 130US of the cell insulating layer may be coplanar with the upper surface 147US of the bit line contact spacer. A height from the bottom surface 146BS of the bit line contact to the upper surface 130US of the cell insulating layer may be equal to the height from the bottom surface 146BS of the bit line contact to the upper surface 146US of the bit line contact. The height from the bottom surface 146BS of the bit line contact to the upper surface 130US of the cell insulating layer may be equal to or greater than the height from the bottom surface 146BS of the bit line contact to the upper surface 120US of the storage contact.

In a cross-sectional view as shown in FIGS. 3 and 5, the cell conductive line 140 may include a first cell conductive line 140_1 on the bit line contact and a second cell conductive line 140_2 on the cell insulating layer 130. For example, a bottom surface of the first cell conductive line 140_1 may be located at a height the same as that of a bottom surface of the second cell conductive line 140_2 based on the bottom surface 146BS of the bit line contact. A height from the bottom surface 146BS of the bit line contact to the bottom surface of the first cell conductive line 140_1 may be equal to a height from the bottom surface 146BS of the bit line contact to the bottom surface of the second cell conductive line 140_2.

Fence patterns 170 may be disposed on the substrate 100 and the cell device isolation layer 105. The fence patterns 170 may be formed to overlap the cell gate structures 110 formed in the substrate 100 and the cell device isolation layer 105. The fence patterns 170 may be formed on the upper surfaces 130US of the cell insulating layer over the cell gate structures 110.

The fence patterns 170 may be disposed between the bit line structures 140ST extending in the second direction DR2. The fence patterns 170 may include at least one of, for example, silicon oxide (SiO₂), silicon nitride (Si₃N₄), silicon oxynitride (SiON), or combinations thereof.

The storage pads 160 are formed on the storage contacts 120. The storage pads 160 may be electrically connected to the storage contacts 120. The storage pads 160 are connected to the storage connection regions 103b of the cell active regions ACT through the storage contacts 120. Here, the storage pads 160 may correspond to the landing pads LP of FIG. 1.

The storage pads 160 may extend down to the storage contacts 120 along the bit line spacers 150. The bit line spacer 150 is disposed between the storage pad 160 and the cell conductive line 140. For example, the storage pad 160 may be electrically insulated from the cell conductive line 140 by the bit line spacer 150.

A height H14 from the bottom surface 146BS of the bit line contact to a lowermost part of the storage pad 160 may be smaller than the height H11 from the bottom surface 146BS of the bit line contact to the bottom surface 140BS of the cell conductive line. Based on the bottom surface 146BS of the bit line contact, the lowermost part of the storage pad 160 may be lower than the upper surface 147US of the bit line contact spacer.

The storage pads 160 may partially overlap upper surfaces of the bit line structures 140ST. The storage pad 160 may include a pad barrier layer 160a and a pad filling layer 160b. The pad barrier layer 160a and the pad filling layer 160b may each include a conductive material including metal.

A pad separation insulating layer 180 may be formed on the storage pads 160 and the bit line structures 140ST. For example, the pad separation insulating layer 180 may be disposed on the cell line capping layer 144. The pad separation insulating layer 180 may define each of the storage pads 160 which are spaced apart from each other. The pad separation insulating layer 180 may not cover the upper surfaces 160US of the storage pads. For example, with respect to the upper surface 100US of the substrate, a height of the upper surface 160US of the storage pad may be equal to a height of an upper surface of the pad separation insulating layer 180.

The pad separation insulating layer 180 may include an insulating material to electrically isolate the storage pads 160 from each other. For example, the pad separation insulating layer 180 may include at least one of, for example, a silicon oxide (SiO₂) layer, a silicon nitride (Si₃N₄) layer, a silicon oxynitride (SiON) layer, or a silicon oxycarbonitride (SiOCN) layer.

An etch stop layer 165 may be formed on the upper surfaces 160US of the storage pads and the upper surface of the pad separation insulating layer 180. The etch stop layer 185 may include at least one of, for example, silicon nitride (Si₃N₄), silicon carbonitride (SiCN), silicon oxycarbonitride (SiOCN), silicon oxycarbide (SiOC), or silicon boron nitride (SiBN).

The information storage part 190 may be disposed on the storage pads 160. The information storage part 190 is connected to the storage pads 160. The information storage part 190 may be in contact with the storage pads 160. A part of the information storage part 190 may be disposed in the etch stop layer 165.

The information storage part 190 may include, for example, capacitors, but the present disclosure is not limited thereto. The information storage part 190 includes the lower electrodes 191, a capacitor dielectric layer 192, and an upper electrode 193. For example, the upper electrode 193 may be a plate upper electrode having a plate form. The information storage part 190 may store charges in the capacitor dielectric layer 192, using a potential difference generated between the lower electrode 191 and the upper electrode 193.

The lower electrodes 191 may be disposed on the storage pads 160. Each of the lower electrodes 191 may have, for example, a pillar shape. However, the present disclosure is not limited thereto. For example, the lower electrode 210 may have a cylindrical shape or other suitable shape.

The capacitor dielectric layer 192 is disposed on the lower electrodes 191. The capacitor dielectric layer 192 may be formed along a profile of the lower electrode 191. For example, the capacitor dielectric layer 192 may be formed along the upper side and a part of the side surfaces of the lower electrode 191, and may be formed along the upper side of the etch stop layer 165. The upper electrode 193 is disposed on the capacitor dielectric layer 192. The upper electrode 193 may cover outer sidewalls of the lower electrodes 191. The upper electrode 193 is illustrated as a single layer. However, this is merely for ease of description, and the present disclosure is not limited thereto.

The lower electrodes 191 and the upper electrode 193 may each include, but are not limited to, a doped semiconductor material, a conductive metal nitride (such as titanium nitride (TiN), tantalum nitride (TaN), niobium nitride (NbN), tungsten nitride (WN), or the like), a metal (such as ruthenium (Ru), iridium (Ir), titanium (Ti), tantalum (Ta), or the like), or a conductive metal oxide (such as iridium oxide (IrOₓ), niobium oxide (NbOₓ), or the like).

The capacitor dielectric layer 192 may include, but is not limited to, one of silicon oxide (SiO₂), silicon nitride (Si₃N₄), silicon oxynitride (SiON), a high-k material, or combinations thereof. The semiconductor memory device according to an embodiment of the present disclosure, the capacitor dielectric layer 192 may have a stacked film structure in which zirconium oxide (ZrO₂), aluminum oxide (Al₂O₃), and zirconium oxide (ZrO₂) are sequentially stacked. In the semiconductor memory device according to an embodiment of the present disclosure, the capacitor dielectric layer 192 may include a dielectric layer containing hafnium (Hf). In the semiconductor memory device according to an embodiment of the present disclosure, the capacitor dielectric layer 192 may have a stacked film structure of a ferroelectric material layer and a paraelectric material layer.

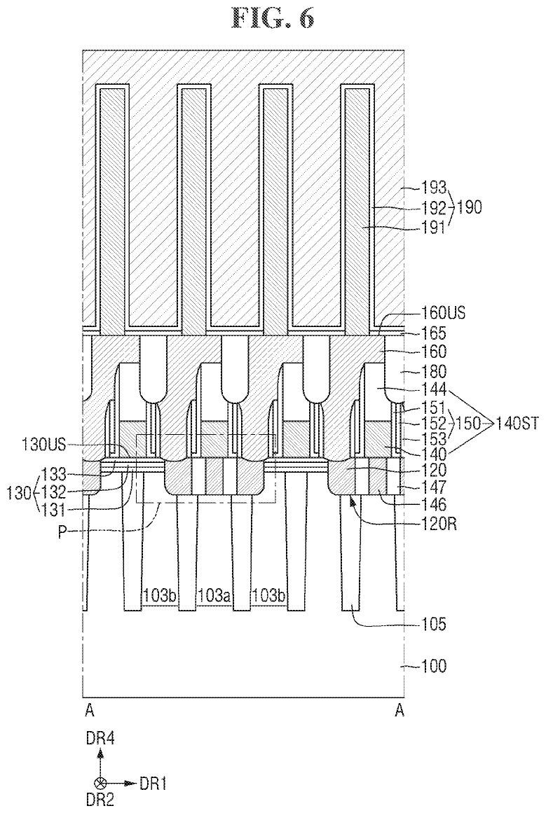

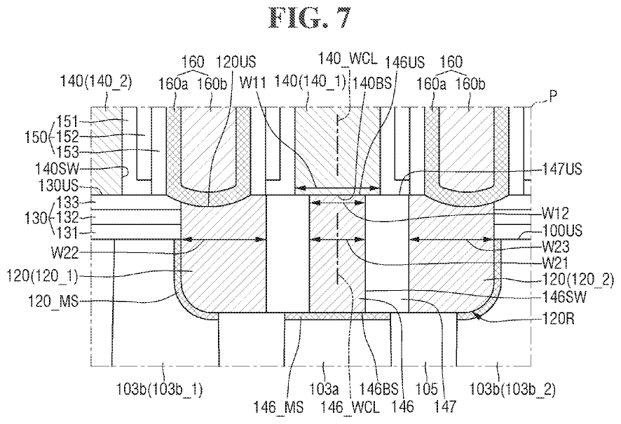

FIGS. 6 and 7 are views for describing a semiconductor memory device according to an embodiment of the present disclosure. For ease of description, differences from the embodiments of FIGS. 1 to 5 will be mainly described. For reference, FIG. 7 is an enlarged view of portion P of FIG. 6.

Referring to FIGS. 6 and 7, in the semiconductor memory device according to an embodiment of the present disclosure, a width W12 of the upper surface 146US of a bit line contact in the first direction DR1 is smaller than a width W11 of a bottom surface 140BS of the cell conductive line in the first direction DR1.

Since a width center line 140_WCL of the cell conductive line is aligned with a width center line 146_WCL of the bit line contact in the fourth direction DR4, the entire upper surface 146US of the bit line contact may be in contact with the bottom surface 140BS of the cell conductive line. In contrast, a part of the bottom surface 140BS of the cell conductive line is not in contact with the upper surface 146US of the bit line contact.

An upper surface 147US of a bit line contact spacer is in contact with the bottom surface 140BS of the cell conductive line. The upper surface 147US of the bit line contact spacer is in contact with the part of the bottom surface 140B S of the cell conductive line that is not in contact with the upper surface 146US of the bit line contact.

At the upper surface 100US of the substrate, a width W22 of a first storage contact 120_1 in the first direction DR1 is greater than or equal to a width W21 of the bit line contact 146 in the first direction DR1. A width W23 of a second storage contact 120_2 in the first direction DR1 may be greater than or equal to the width W21 of the bit line contact 146 in the first direction DR1.

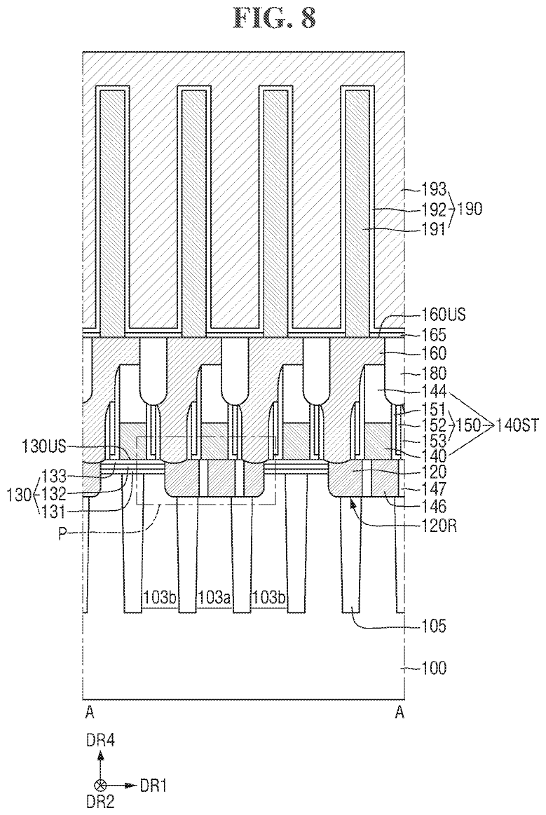

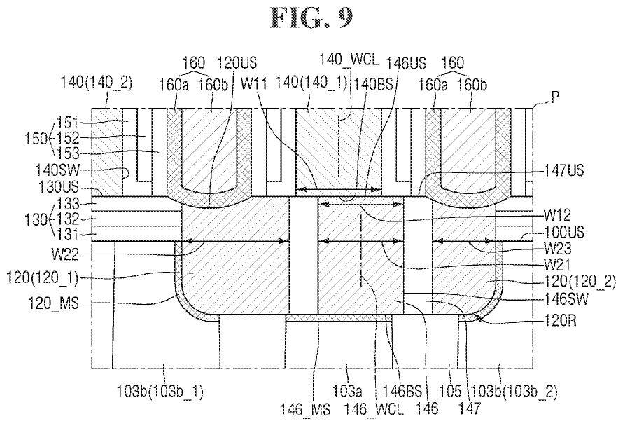

FIGS. 8 and 9 are views for describing a semiconductor memory device according to an embodiment of the present disclosure. For ease of description, differences from the embodiments of FIGS. 1 to 5 will be mainly described. For reference, FIG. 9 is an enlarged view of portion P of FIG. 8.

Referring to FIGS. 8 and 9, in a semiconductor memory device according to an embodiment of the present disclosure, a width center line 140_WCL of a cell conductive line is misaligned with a width center line 146_WCL of a bit line contact in the fourth direction DR4.

Since the width center line 140_WCL of the cell conductive line is not aligned with the width center line 146_WCL of the bit line contact in the fourth direction DR4, a bottom surface 140BS of the cell conductive line may be in contact with an upper surface 147US of a bit line contact spacer.

Unlike in the drawings, a width W12 of an upper surface 146US of the bit line contact in the first direction DR1 may be smaller than a width W11 of the bottom surface 140BS of the cell conductive line in the first direction DR1.

At the upper surface 100US of a substrate, a width W22 of a first storage contact 120_1 is greater than a width W23 of a second storage contact 120_2. At the upper surface 100US of the substrate, the width W22 of the first storage contact 120_1 is greater than a width W21 of the bit line contact 146. In an embodiment of the present disclosure, at the upper surface 100US of the substrate, a width W23 of a second storage contact 120_2 may be greater than the width W21 of the bit line contact 146. In an embodiment of the present disclosure, the width W23 of the second storage contact 120_2 may be equal to the width W21 of the bit line contact 146. In an embodiment of the present disclosure, the width W23 of the second storage contact 120_2 may be smaller than the width W21 of the bit line contact 146.

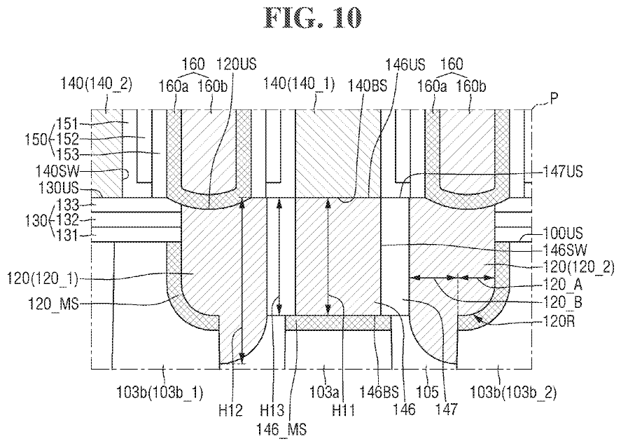

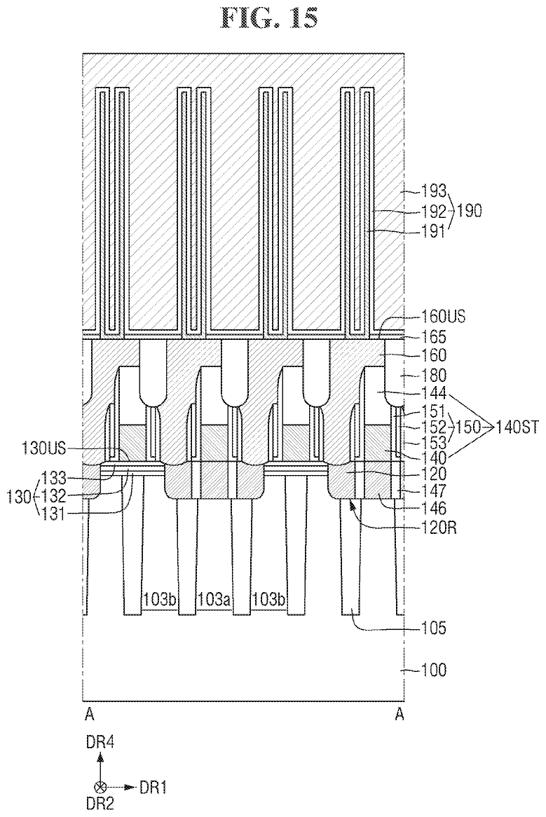

FIGS. 10 to 14 are views each for describing a semiconductor memory device according to an embodiment of the present disclosure. FIG. 15 is a view for describing a semiconductor memory device according to an embodiment of the present disclosure. For ease of description, differences from the embodiments of FIGS. 1 to 5 will be mainly described. For reference, FIGS. 10 to 14 are enlarged views of portion P of FIG. 3.

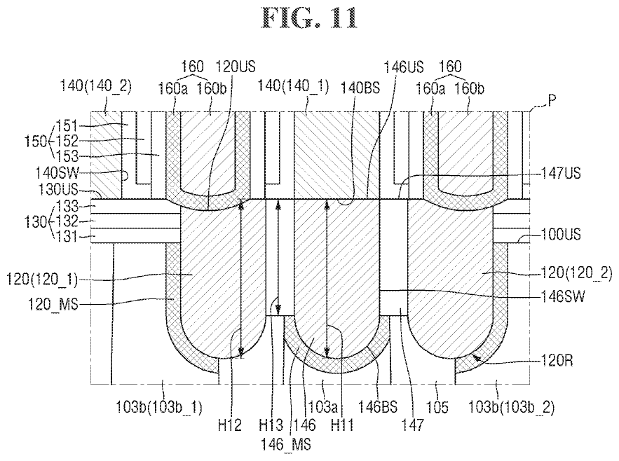

Referring to FIGS. 10 and 11, in a semiconductor memory device according to an embodiment of the present disclosure, a height H13 of a bit line contact spacer 147 may be smaller than a height H12 of a storage contact 120.

In a cross-sectional view, with respect to an upper surface 130US of a cell insulating layer, a lowermost part of the storage contact 120 is lower than a bottom surface of the bit line contact spacer 147.

In FIG. 10, the storage contact 120 may include a first portion 120_A that overlaps a storage connection region 103b in the fourth direction DR4, and a second portion 120_B that overlaps a cell device isolation layer 105 in the fourth direction DR4. The height H12 of the storage contact 120 may be a height of the second portion 120_B of the storage contact. The height of the second portion 120_B of the storage contact is greater than a height of the first portion 120_A of the storage contact.

At a boundary between the first portion 120_A of the storage contact and the second portion 120_B of the storage contact, a bottom surface of the storage contact 120 may discontinuously change.

In FIG. 11, a bottom surface 146BS of the bit line contact may have a convex shape. A bottom surface of the storage contact 120 may have a convex shape like the bottom surface 146BS of the bit line contact.

At a boundary between the substrate 100 and the cell device isolation layer 105, the bottom surface of the storage contact 120 may continuously change.

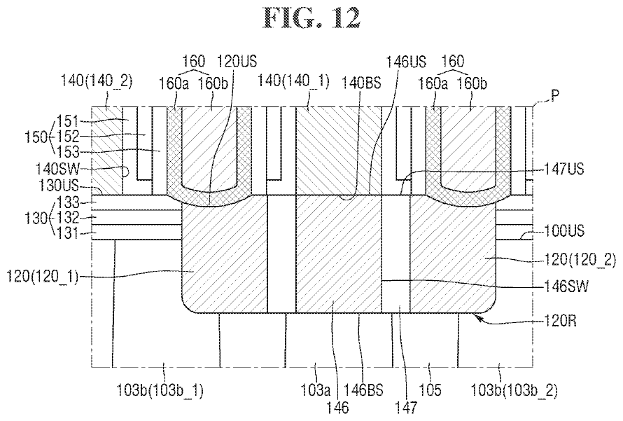

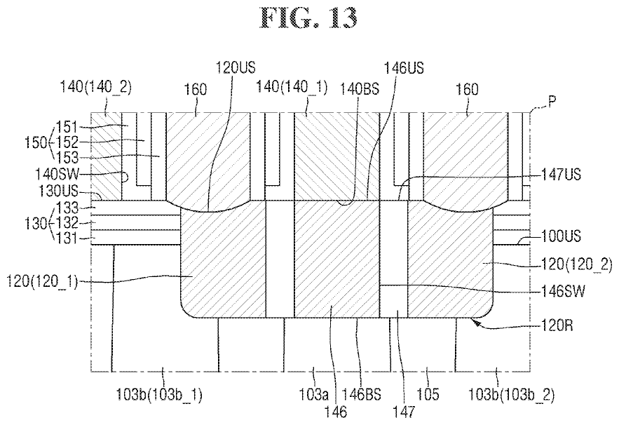

Referring to FIGS. 12 and 13, in the semiconductor memory device according to an embodiment of the resent disclosure, a storage contact silicide layer 120_MS (see FIG. 5) is not disposed between the storage contact 120 and the substrate 100. The bit line contact silicide layer 146_MS (see FIG. 5) is not disposed between the bit line contact 146 and the substrate 100.

The bit line contact 146 and the storage contact 120 may include, for example, a semiconductor material doped with impurities. In other words, since the bit line contact 146 and the storage contact 120 may include a semiconductor material doped with impurities not a metal, there is no need to have metal silicide materials in the interfaces to provide reliable metal-semiconductor contact between the substrate 100 and the storage contact 120 and the bit line contact 146.

In FIG. 12, the storage pad 160 may include a pad barrier layer 160a and a pad filling layer 160b which each include a conductive material including metal.

In FIG. 13, the storage pad 160 may include, for example, a semiconductor material doped with impurities. For example, in FIG. 13, the storage pad 160 may be formed as a single layer, and does not include a pad barrier layer 160a and a pad filling layer 160b.

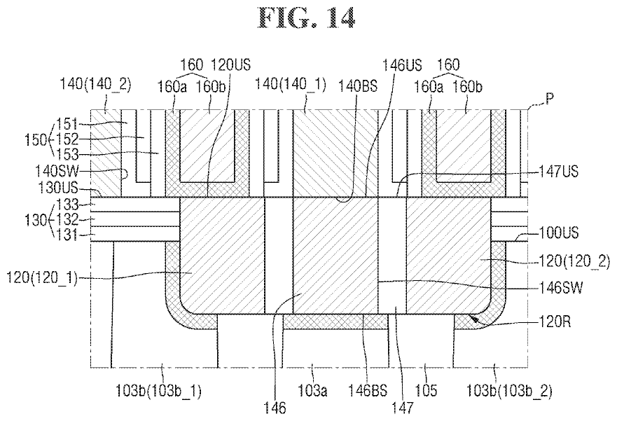

Referring to FIG. 14, in the semiconductor memory device according to an embodiment of the present disclosure, the upper surface 120US of the storage contact may be flat.

The upper surface 120US of the storage contact may be coplanar with the upper surface 130US of the cell insulating layer.

Referring to FIG. 15, in the semiconductor memory device according to an embodiment of the present disclosure, lower electrodes 191 may each have a cylindrical shape.

The lower electrode 191 may include a bottom part extending along the upper surface 160US of the storage pad and sidewall parts extending from the bottom part in the fourth direction DR4.

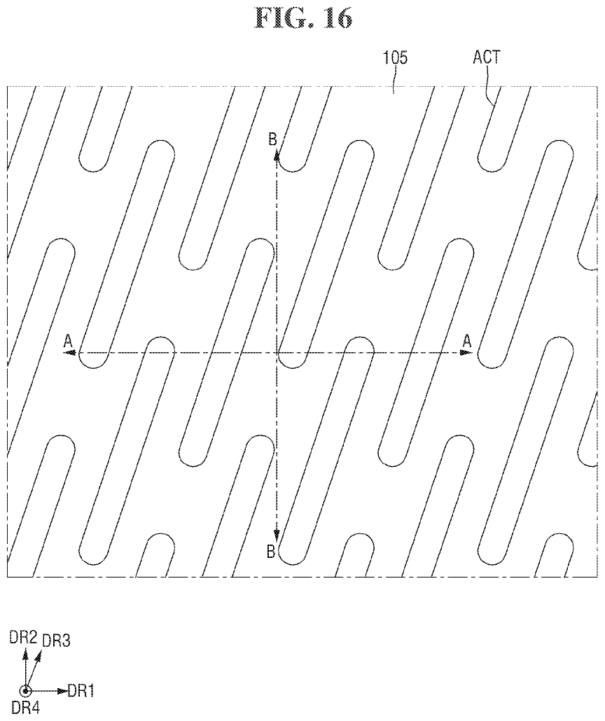

FIGS. 16 to 40 are views illustrating intermediate stages of fabrication, provided to explain a method of fabricating a semiconductor memory device according to an embodiment of the present disclosure. In the description of the fabricating method, repeated contents of those explained using FIGS. 1 to 15 will be briefly explained or omitted.

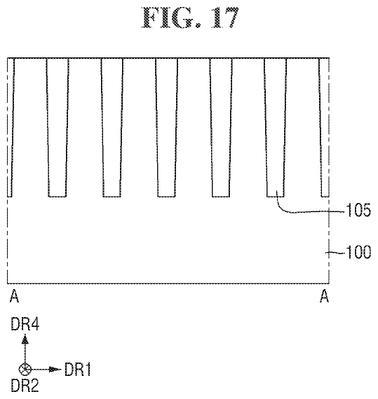

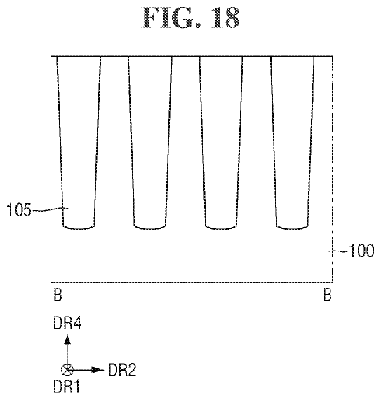

For reference, FIGS. 17 and 18 are cross-sectional views taken along lines A-A and B-B, respectively.

Referring to FIGS. 16 to 18, a cell device isolation layer 105 may be formed in a substrate 100.

The substrate 100 may include cell active regions ACT defined by the cell device isolation layer 105. The cell active region ACT may have a bar shape extending in the third direction DR3 which may be inclined by a predetermined angle with respect to the first direction DR1 or the second direction DR2. In an embodiment of the present disclosure, the predetermined angle may range from about 10° to about 80°.

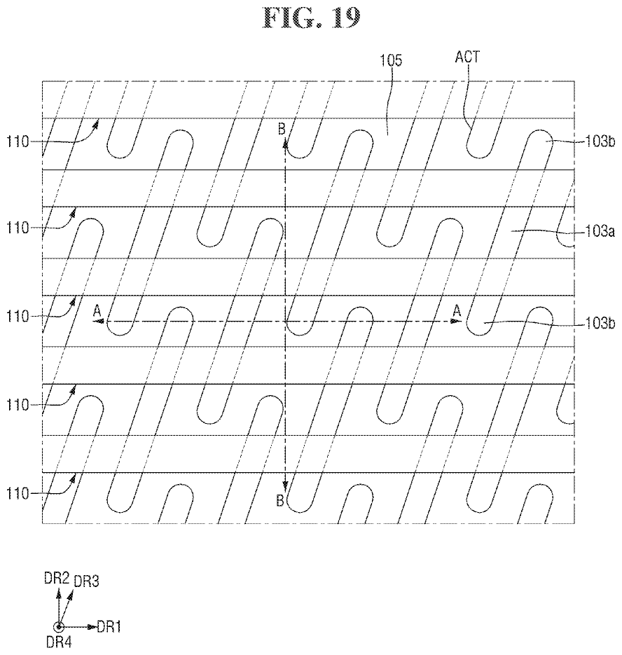

Referring to FIGS. 19 to 21, cell gate electrodes 112 are formed in the substrate 100 and the cell device isolation layer 105.

The cell gate electrodes 112 may extend in the first direction DR1, and may be spaced apart from each other in the second direction DR2.

Cell gate structures 110 extending in the first direction DR1 are formed in the substrate 100 and the cell device isolation layer 105. Each of the cell gate structures 110 may include a cell gate trench 115, a cell gate insulating layer 111, a cell gate electrode 112, a cell gate capping pattern 113, and a cell gate capping conductive layer 114.

The cell gate electrode 112 intersects the cell active region ACT. The cell active region ACT may be divided into bit line connection region 103a and storage connection regions 103b by the cell gate electrode 112.

The cell active region ACT may include the bit line connection region 103a located in a middle part of the cell active region ACT and the storage connection regions 103b respectively located at opposite ends of the cell active region ACT.

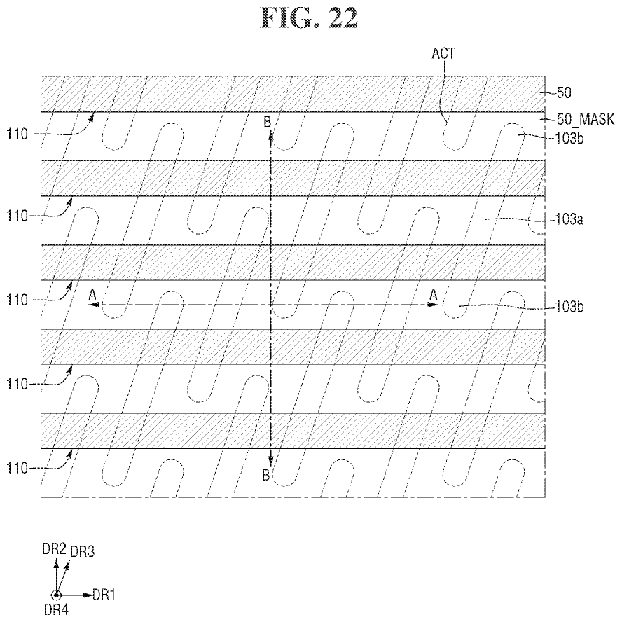

Referring to FIGS. 22 to 24, a cell insulating layer 130 may be formed on the substrate 100 and the cell device isolation layer 105. The cell insulating layer 130 may be a multilayer including a first cell insulating layer 131, a second cell insulating layer 123, and a third cell insulating layer 133 sequentially stacked.

A pre-mask layer 50 is formed on the cell insulating layer 130. The pre-mask layer 50 may include, but is not limited to, for example, polysilicon (p-Si), amorphous silicon (a-Si), polysilicon-germanium (p-SiGe), or amorphous silicon-germanium (a-SiGe).

First mask patterns 50_MASK are formed on the pre-mask layer 50. Each first mask pattern 50_MASK may be in the shape of a line extending in the first direction DR1. The first mask patterns 50_MASK may overlap the cell gate structures 110 in the fourth direction DR4. The first mask patterns 50_MASK may each include, but are not limited to, for example, an amorphous carbon layer (ACL).

Referring to FIGS. 22 to 27, the pre-mask layer 50 may be partially removed using the first mask patterns 50_MASK as a mask.

First contact mask patterns 55 may be formed on the cell insulating layer 130 through patterning of the pre-mask layer 50. Each first contact pattern 55 may be in the shape of line extending in the first direction DR1. The first contact mask patterns 55 may overlap the cell gate structures 110 in the fourth direction DR4.

After the first contact mask patterns 55 are formed, the first mask patterns 50_MASK are removed.

Thereafter, a filling mask pattern 56 may be formed between each pair of first contact mask patterns 55 adjacent to each other in the second direction DR2. The filling mask patterns 56 may be formed on the cell insulating layer 130. The filling mask pattern 56 may be formed between each pair of the cell gate structures 110 adjacent to each other in the second direction DR2. The filling mask pattern 56 may include, but is not limited to, for example, silicon oxide (SiO₂).

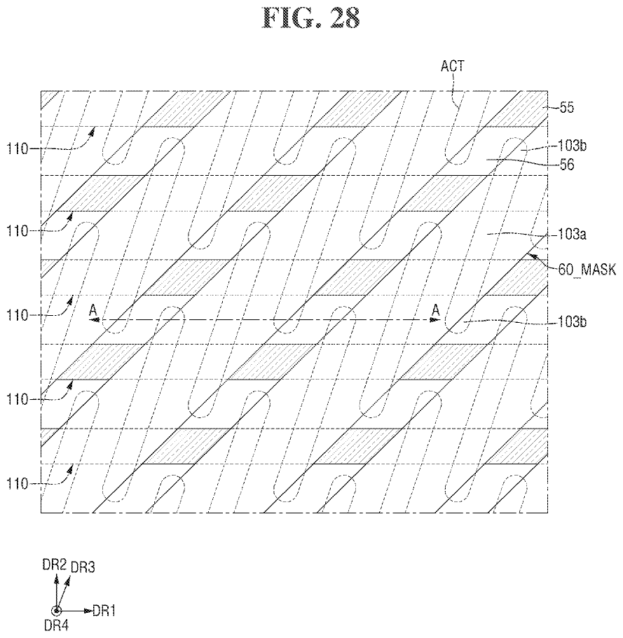

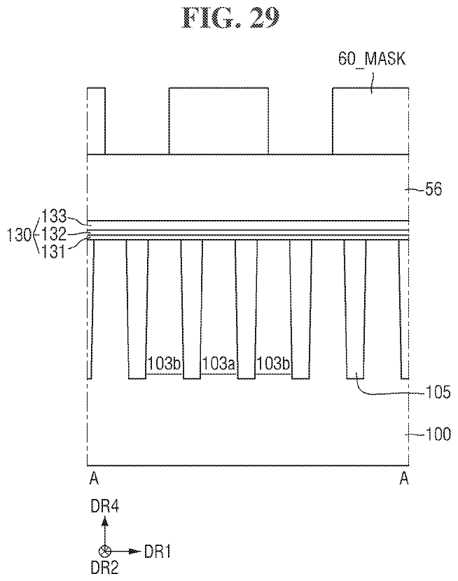

Referring to FIGS. 28 and 29, second mask patterns 60_MASK are formed on the first contact mask patterns 55 and the filling mask patterns 56.

The second mask pattern 60_MASK may be in the shape of a line extending in a fifth direction. The fifth direction may be located between the first direction DR1 and the third direction DR3. The second mask pattern 60_MASK may cover the bit line connection region 103a. The second mask pattern 60_MASK may overlap the bit line connection regions 103a of the cell active regions ACT in the fourth direction DR4.

The second mask pattern 60_MASK may include, but is not limited to, a spin-on-hardmask (SOH).

Unlike in the drawings, the second mask patterns 60_MASK may extend in the third direction DR3 in which the cell active regions ACT extend.

Referring to FIGS. 28 to 31, the filling mask pattern 56 may be partially removed using the second mask patterns 60_MASK as a mask.

Mask filling patterns 56P may be formed on the cell insulating layer 130 by partially removing the filling mask pattern 56. The cell insulating layer 130 may be exposed while the mask filling patterns 56P are formed. While the mask filling patterns 56P are formed, the first contact mask patterns 55 remain without being removed.

The mask filling patterns 56P cover the bit line connection regions 103a. In addition, the mask filling patterns 56P may partially cover the storage connection regions 103b located at opposite sides of the bit line connection region 103a.

After the mask filling patterns 56P are formed, the second mask patterns 60_MASK are removed.

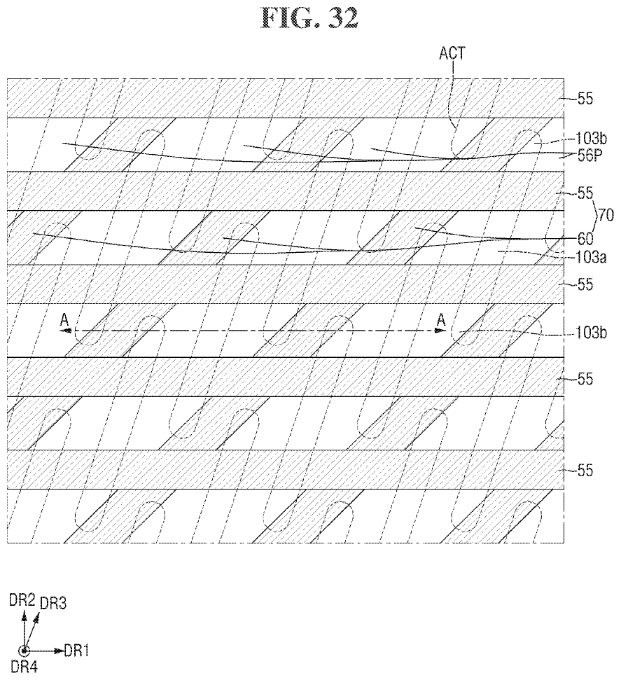

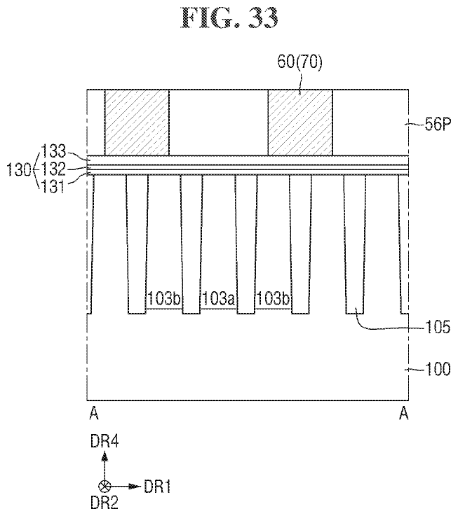

Referring to FIGS. 32 and 33, second contact mask patterns 60 are formed on the exposed cell insulating layer 130.

The second contact mask pattern 60 is formed between the first contact mask patterns 55 adjacent to each other in the second direction DR2. The second contact mask pattern 60 is formed between the mask filling patterns 56P adjacent to each other in the first direction DR1.

The second contact mask patterns 60 may include, but is not limited to, for example, polysilicon (p-Si), amorphous silicon (a-Si), polysilicon-germanium (p-SiGe), or amorphous silicon-germanium (a-SiGe).

As the second contact mask patterns 60 are formed, a contact mask pattern 70 is formed on the substrate 100. The contact mask pattern 70 may be formed on the cell insulating layer 130. The contact mask patterns 70 may include the first contact mask patterns 55 and the second contact mask patterns 60.

The contact mask pattern 70 may surround the mask filling patterns 56P disposed in an island shape. In other words, the mask filling patterns 56P may be disposed in the contact mask pattern 70.

Referring to FIGS. 32 to 34, contact recesses 120R are formed in the substrate 100 and the cell device isolation layer 105 using the contact mask pattern 70 as a mask.

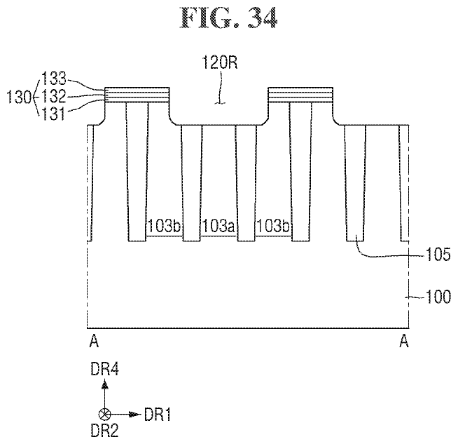

The contact recess 120R may be formed over the bit line connection region 103a and the storage connection regions 103b. In the cross-sectional view shown in FIG. 34, each contact recess 120R may be formed over one bit line connection region 103a and two storage connection regions 103b.

While the contact recess 120R is formed, the contact mask pattern 70 and the mask filling patterns 56P may be removed, but the present disclosure is not limited thereto. In addition, while the contact recess 120R is formed, a third cell insulating layer 133 of the cell insulating layer 130 may be partially removed, but the present disclosure is not limited thereto. Unlike in the drawings, while the contact recess 120R is formed, the third cell insulating layer 133 of the cell insulating layer 130 may be removed.

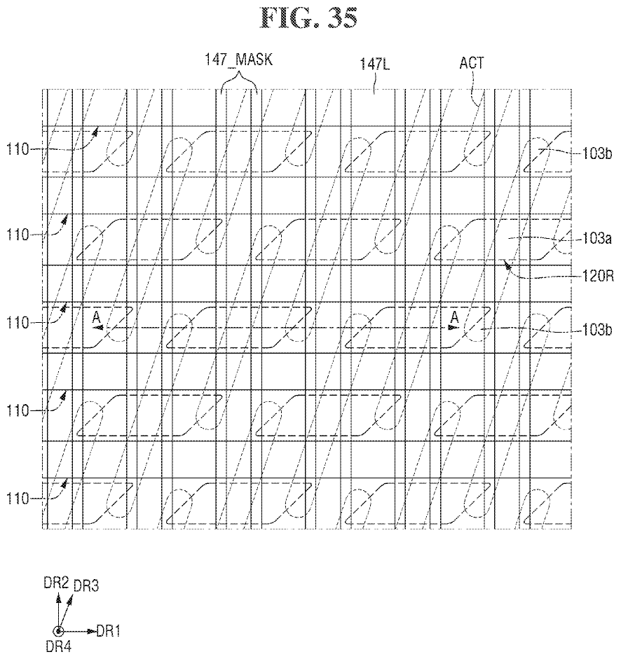

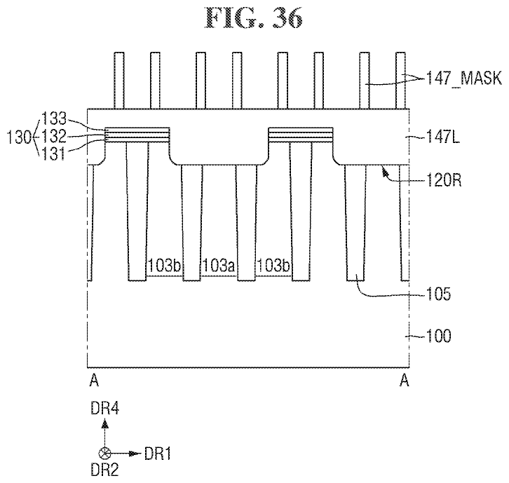

Referring to FIGS. 35 and 36, a spacer layer 147L may be formed on the substrate 100.

The spacer layer 147L may fill the contact recess 120R, and may cover the cell insulating layer 130.

The spacer layer 147L may include at least one of, for example, silicon oxycarbide (SiOC), silicon nitride (Si₃N₄), silicon oxynitride (SiON), silicon oxide (SiO₂), silicon carbonitride (SiCN), or silicon oxycarbonitride (SiOCN).

Spacer mask patterns 147_MASK are formed on the spacer layer 147L. The spacer mask pattern 147_MASK may be in the shape of a line extending in the second direction DR2. A plurality of bit line connection regions 103a may be located between a pair of spacer mask patterns 147_MASK.

The spacer mask patterns 147_MASK may each include, but are not limited to, for example, an amorphous carbon layer (ACL).

Referring to FIGS. 35 to 37, the spacer layer 147L may be patterned using the spacer mask patterns 147_MASK as a mask.

Bit line contact spacers 147 may be formed by patterning the spacer layer 147L. Some bit line contact spacers 147 may be formed in the contact recess 120R. The bit line contact spacers 147 may extend in the second direction DR2.

The bit line contact spacers 147 may divide the contact recess 120R into a first region 120R_1 and second regions 120R_2. The first region 120R_1 of the contact recess may be defined on the bit line connection region 103a. The second region 120R_2 of the contact recess may be defined on the storage connection region 103b.

In an embodiment of the present disclosure, before the spacer layer 147L is formed, a storage contact silicide layer 120_MS and a bit line contact silicide layer 146_MS may be formed.

In an embodiment of the resent disclosure, after the bit line contact spacers 147 are formed, the storage contact silicide layer 120_MS and the bit line contact silicide layer 146_MS may be formed.

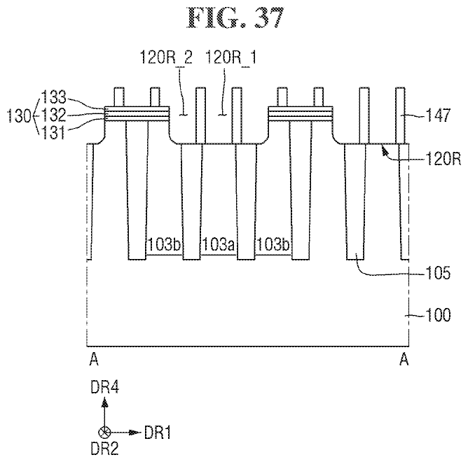

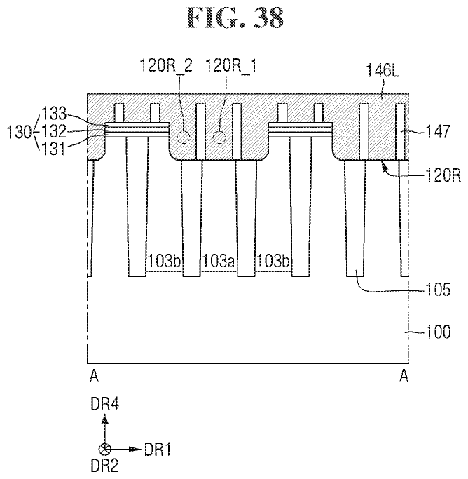

Referring to FIGS. 37 and 38, a contact conductive layer 146L may be formed on the substrate 100.

The contact conductive layer 146L may fill the first region 120R_1 and the second region 120R_2 of the contact recess. The contact conductive layer 146L may be formed on the upper surface of the cell insulating layer 130. The contact conductive layer 146L may cover the bit line contact spacers 147.

The contact conductive layer 146L may be formed using, for example, chemical vapor deposition (CVD), but the present disclosure is not limited thereto.

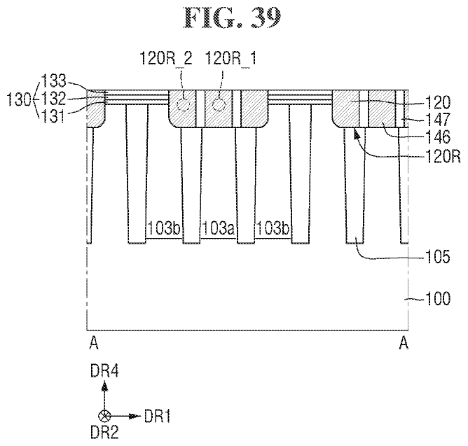

Referring to FIG. 39, the bit line contact 146 and the storage contact 120 are formed in the contact recess 120R.

The bit line contact 146 may fill the first region 120R_1 of the contact recess. The storage contact 120 may fill the second region 120R_2 of the contact recess.

The bit line contact 146 and the storage contact 120 may be formed by partially removing the contact conductive layer 146L. Thus, the bit line contact 146 and the storage contact 120 may include the same material. Also, the bit line contact 146 and the storage contact 120 may be formed at the same level. Since the bit line contact 146 and the storage contact 120 are formed at the same time, the present disclosure may employ less etch steps and/or more simplified etch steps in comparison to the processes commonly used in forming a bit line contact and a storage contact sequentially and separately. While the bit line contact 146 and the storage contact 120 are formed, the bit line contact spacers 147 protruding further upward than the upper surface of the cell insulating layer 130. That is, as the bit line contact spacers 147 protruding further upward than the upper surface of the cell insulating layer 130 are removed, the bit line contact spacers 147 may be disposed within the contact recess 120R. By forming the bit line contact spacers 147 in the contact recess 120R first, then forming the bit line contact 146 and the storage contacts 120 self-aligned through the bit line contact spacers 147 within the contact recess 120R, the bit line contact 146 and the storage contacts 120 may be reliably separated within the contact recess 120R.

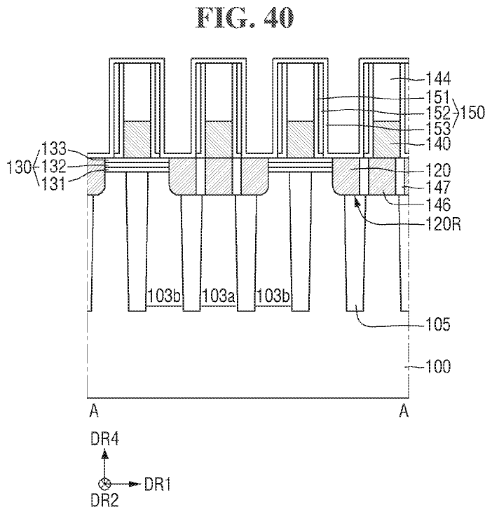

Referring to FIG. 40, a cell conductive line 140 and a cell line capping layer 144 may be formed on the bit line contact 146. The cell conductive line 140 extends in the second direction DR2.

Thereafter, a bit line spacer 150 is formed on a sidewall of the cell conductive line 140 and a sidewall of the cell line capping layer 144. The bit line spacer 150 may include a first spacer 151, a second spacer 152, and a third spacer 153. The third spacer 153 may cover the upper surface of the storage contact 120.

Thereafter, referring to FIG. 3, the storage pad 160 is formed on the storage contact 120. While the storage pad 160 is formed, the third spacer 153 covering the upper surface of the storage contact 120 is removed. An information storage part 190 is formed on the bit line spacer 150. The information storage part 190 is formed on the storage pad 160, and connected to the storage contact 120 through the storage pad 160.

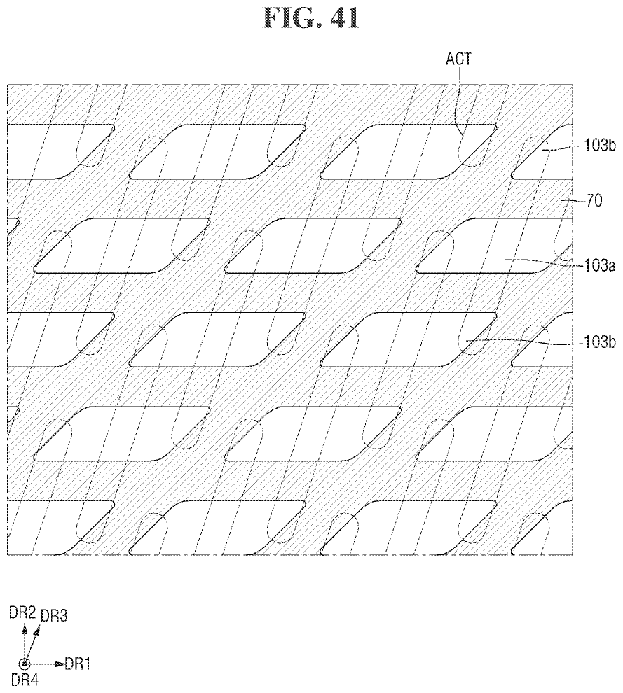

FIGS. 41 to 44 are views each for describing a method of fabricating a semiconductor memory device according to an embodiment of the present disclosure. For reference, FIGS. 41 to 44 are views for describing the contact mask pattern 70 as shown in FIG. 32.

In FIG. 41, the space surrounded by the contact mask pattern 70 may have a parallelogram shape with rounded corners. The space surrounding by the contact mask pattern 70 may correspond to the mask filling pattern 56P of FIG. 32.

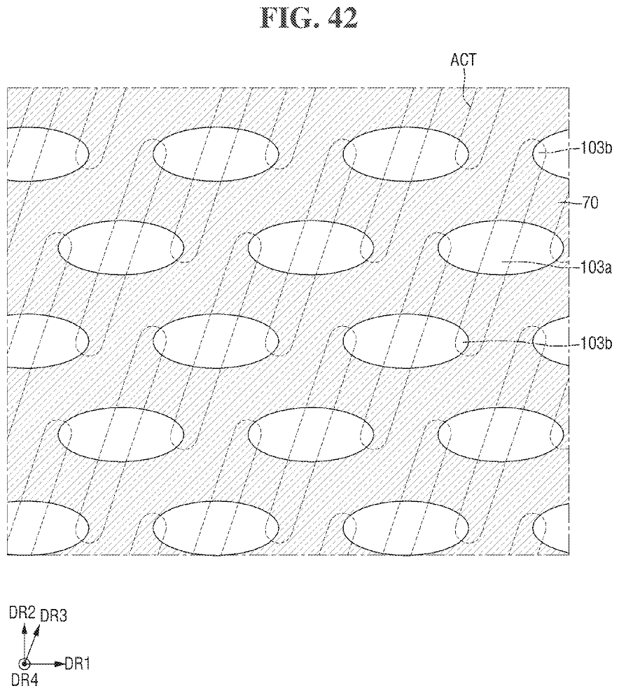

In FIG. 42, the space surrounded by the contact mask pattern 70 may have an elliptical shape.

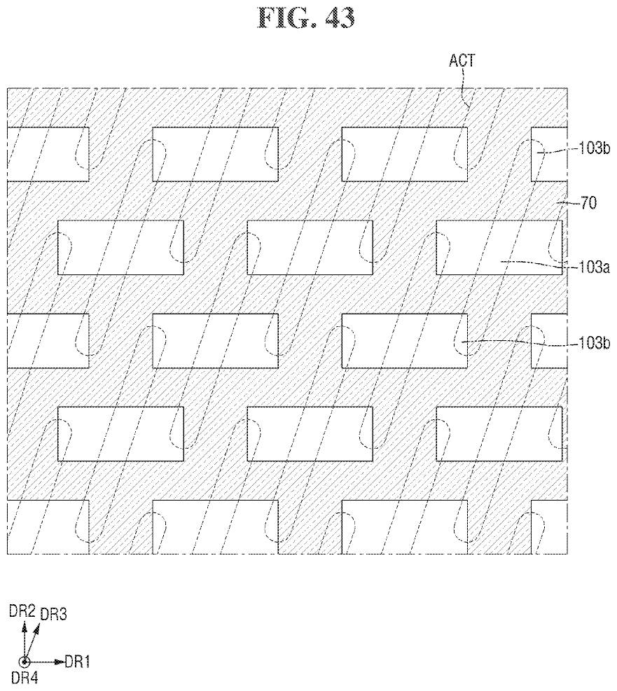

In FIG. 43, the space surrounded by the contact mask pattern 70 may have a rectangular shape. Unlike in the drawings, the space surrounded by the contact mask pattern 70 may have a rectangular shape with rounded corners.

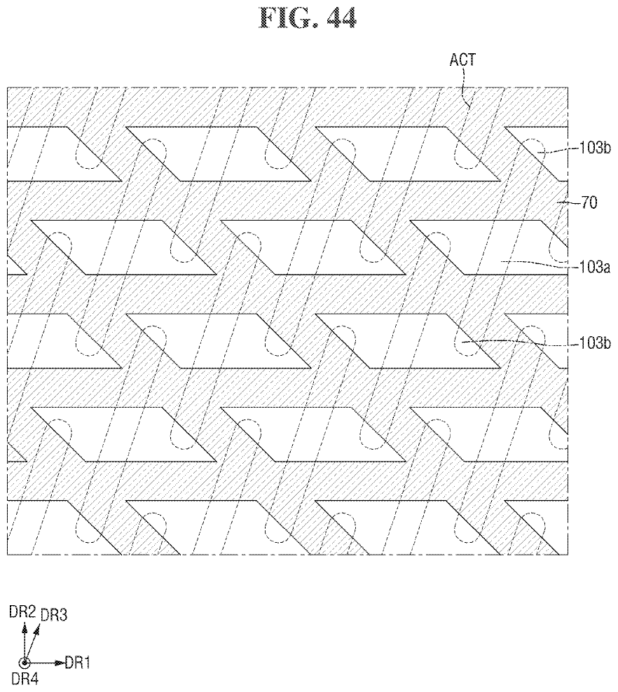

In FIG. 44, the space surrounded by the contact mask pattern 70 may have a parallelogram shape. A portion of the contact mask pattern 70 corresponding to the second contact mask pattern 60 of FIG. 32 may be inclined in a sixth direction that is different from the direction of the second contact mask pattern 60 of FIG. 32.

In concluding the detailed description, those skilled in the art will appreciate that many variations and modifications may be made to the preferred embodiments without departing from the spirit and scope of the present disclosure as defined in the appended claims. Therefore, the disclosed preferred embodiments of the present disclosure are used in a generic and descriptive sense only and not for purposes of limitation.

What is claimed is:

1. A semiconductor memory device comprising:
a substrate including an active region defined by a device isolation layer;
a bit line which is disposed on the substrate and extends in a first direction;
a bit line contact which is disposed between the bit line and the substrate and connects the bit line to the active region;
a bit line spacer which extends along a sidewall of the bit line; and
a bit line contact spacer which extends along a sidewall of the bit line contact and does not extend along the sidewall of the bit line.

2. The semiconductor memory device of claim 1, further comprising:
a storage contact disposed on the substrate; and
a storage pad disposed on the storage contact,
wherein the bit line contact spacer is disposed between the bit line contact and the storage contact.

3. The semiconductor memory device of claim 2, wherein an upper surface of the bit line contact is at a level the same as or higher than that of an upper surface of the storage contact based on a bottom surface of the bit line contact.

4. The semiconductor memory device of claim 2, wherein a width of the bit line contact in a second direction orthogonal to the first direction is smaller than or equal to a width of the storage contact in the second direction.

5. The semiconductor memory device of claim 2, wherein a height of the bit line contact spacer is smaller than or equal to a height of the storage contact.

6. The semiconductor memory device of claim 2, further comprising an information storage part disposed on the storage pad and being in contact with the storage pad.

7. The semiconductor memory device of claim 1, wherein a width of an upper surface of the bit line contact in a second direction orthogonal to the first direction is smaller than or equal to a width of a bottom surface of the bit line in the second direction.

8. The semiconductor memory device of claim 1, wherein a height from a bottom surface of the bit line contact to an upper surface of the bit line contact is equal to a height from the bottom surface of the bit line contact to an upper surface of the bit line contact spacer.

9. The semiconductor memory device of claim 1, wherein each of the bit line and the bit line contact includes a width center line, and
the width center line of the bit line is misaligned with the width center line of the bit line contact in a thickness direction of the substrate.

10. The semiconductor memory device of claim 1, wherein the bit line contact spacer is a single layer, and
the bit line spacer is a multilayer.

11. A semiconductor memory device comprising:
a substrate which includes first to third active regions defined by a device isolation layer, the second active region being disposed between the first active region and the third active region;
a bit line contact which is disposed on the substrate and connected to the second active region;
a first storage contact which is disposed on the substrate and connected to the first active region;
a second storage contact which is disposed on the substrate and connected to the third active region;
a bit line contact spacer which is disposed on the substrate and is disposed between the bit line contact and the first storage contact and between the bit line contact and the second storage contact; and
a bit line which is disposed on the bit line contact, extends in a first direction, and is in contact with an upper surface of the bit line contact spacer.

12. The semiconductor memory device of claim 11, further comprising a bit line spacer which extends along a sidewall of the bit line,
wherein the bit line spacer is in contact with a sidewall of the bit line and not in contact with a sidewall of the bit line contact.

13. The semiconductor memory device of claim 11, wherein a width of the bit line contact in a second direction orthogonal to the first direction is smaller than a width of the first storage contact in the second direction.

14. The semiconductor memory device of claim 13, wherein the width of the first storage contact in the second direction is equal to a width of the second storage contact in the second direction.

15. The semiconductor memory device of claim 13, wherein the width of the first storage contact in the second direction is greater than a width of the second storage contact in the second direction.

16. The semiconductor memory device of claim 11, wherein a width of an upper surface of the bit line contact in a second direction orthogonal to the first direction is smaller than or equal to a width of a bottom surface of the bit line in the second direction.

17. A semiconductor memory device comprising:
a substrate which includes an active region defined by a device isolation layer and extending in a first direction, the active region including a first region and second regions defined at opposite sides of the first region;
a word line which extends in a second direction in the substrate and the device isolation layer and crosses the first region of the active region and the second region of the active region;
a bit line which is disposed on the substrate and the device isolation layer, extends in a third direction orthogonal to the second direction, and is connected to the first region of the active region;
a bit line contact which is disposed between the bit line and the substrate and connected to the bit line, a width of an upper surface of the bit line contact in the second direction being smaller than a width of a bottom surface of the bit line in the second direction;
a storage contact which is disposed on the substrate and connected to a second region of an other active region adjacent to the active region;
a storage pad which is disposed on the storage contact and connected to the storage contact; and
a capacitor which is disposed on the storage pad and connected to the storage pad.

18. The semiconductor memory device of claim 17, further comprising a bit line contact spacer disposed between the bit line contact and the storage contact,
wherein the upper surface of the bit line contact is in contact with the bottom surface of the bit line.

19. The semiconductor memory device of claim 18, further comprising a bit line spacer disposed between the bit line and the storage pad,
wherein the bit line spacer is not in contact with a sidewall of the bit line contact.

20. The semiconductor memory device of claim 17, wherein a height from a bottom surface of the bit line contact to a lowermost part of the storage pad is smaller than or equal to a height from the bottom surface of the bit line contact to the bottom surface of the bit line.
